(19) United States
(12) Patent Application Publication
(10) Pub. No.: US 2026/0107669 A1
(43) Pub. Date: Apr. 16, 2026

(54) DISPLAY DEVICE AND ELECTRONIC DEVICE INCLUDING THE SAME

(71) Applicant: Samsung Display Co., LTD., Yongin-si (KR)

(72) Inventors: Sunghoon YANG, Yongin-si (KR); Hyuneok SHIN, Yongin-si (KR); Inyoung JUNG, Yongin-si (KR)

(21) Appl. No.: 19/269,823

(22) Filed: Jul. 15, 2025

(30) Foreign Application Priority Data
Oct. 16, 2024 (KR) 10-2024-0141356

(51) Int. Cl. H10K 59/80; H10K 102/00

(52) U.S. Cl. CPC H10K 59/8792; H10K 59/879; H10K 2102/331

(57) ABSTRACT

A display device includes: a first light-emitting element located in a first pixel area, a first nanostructure array located in the first pixel area on the first light-emitting element, where the first nanostructure array includes first nanostructures repeatedly arranged along a first direction and a second direction crossing the first direction, a second light-emitting element located in a second pixel area spaced apart from the first pixel area in a plan view, and a second nanostructure array located in the second pixel area on the second light-emitting element, where the second nanostructure array includes second nanostructures repeatedly arranged along the first direction and the second direction. Lengths of the first nanostructures in a horizontal direction thereof change along the first direction. Lengths of the second nanostructures in a horizontal direction thereof change along the first direction.

This application claims priority to Korean Patent Application No. 10-2024-0141356, filed on Oct. 16, 2024, and all the benefits accruing therefrom under 35 U.S.C. § 119, the content of which in its entirety is herein incorporated by reference.

### BACKGROUND

### 1. Field

The present disclosure relates to a display device and an electronic device including the display device. More particularly, the present disclosure relates to a display device providing visual information and an electronic device including the display device.

### 2. Description of the Related Art

A display device is a device that displays an image for providing visual information to a user. Among display devices, an organic light-emitting diode display device are widely used in various fields.

External light incident on the display device may be reflected from wiring, electrodes, and/or the like. In order to block reflection of such external light, the display device may include a polarizing plate and/or the like. In addition, the display device may include a light-emitting element that emits light. The display device may include a lens and/or the like that condenses light emitted from the light-emitting element.

### SUMMARY

Embodiments of the present disclosure provide a display device with reduced manufacturing cost.

Embodiments of the present disclosure provide an electronic device including the display device.

A display device according to one or more embodiments includes a first light-emitting element located in a first pixel area, a first nanostructure array located in the first pixel area on the first light-emitting element, where the first nanostructure array includes first nanostructures repeatedly arranged along a first direction and a second direction crossing the first direction, a second light-emitting element located in a second pixel area spaced apart from the first pixel area in a plan view, and a second nanostructure array located in the second pixel area on the second light-emitting element, where the second nanostructure array includes second nanostructures repeatedly arranged along the first direction and the second direction.

In one or more embodiments, lengths of the first nanostructures in a horizontal direction thereof may change along the first direction.

In one or more embodiments, lengths of the second nanostructures in a horizontal direction thereof may change along the first direction.

In one or more embodiments, lengths of the first nanostructures in a vertical direction thereof may change along the first direction and lengths of the second nanostructures in a vertical direction thereof may change along the first direction.

In one or more embodiments, the lengths of the first nanostructures in the horizontal direction thereof may change along the second direction, and the lengths of the second nanostructures in the horizontal direction thereof may change along the second direction.

In one or more embodiments, a separation distance between two adjacent first nanostructures of the first nanostructures and a separation distance between two adjacent second nanostructures of the second nanostructures may be different from each other.

In one or more embodiments, the first pixel area may emit red light, the second pixel area may emit green light, and the separation distance between the two adjacent first nanostructures of the first nanostructures may be greater than the separation distance between the two adjacent second nanostructures of the second nanostructures.

In one or more embodiments, heights of the first nanostructures may change along the first direction and heights of the second nanostructures may change along the first direction.

In one or more embodiments, the heights of the first nanostructures may change along the first direction and the heights of the second nanostructures may change along the first direction.

In one or more embodiments, inclination angles of the first nanostructures with respect to the first direction may change along the first direction and inclination angles of the second nanostructures with respect to the first direction may change along the first direction.

In one or more embodiments, the inclination angles of the first nanostructures with respect to the first direction may change along the second direction and the inclination angles of the second nanostructures with respect to the first direction may change along the second direction.

In one or more embodiments, the lengths of the first nanostructures in the horizontal direction thereof may change gradually along the first direction and the lengths of the second nanostructures in the horizontal direction thereof may change gradually along the first direction.

In one or more embodiments, at least one of the first nanostructures may be located between the first pixel area and the second pixel area.

In one or more embodiments, at least one of the second nanostructures may be located between the first pixel area and the second pixel area.

In one or more embodiments, the first nanostructure array may include sub-nanostructure arrays spaced apart from each other in a plan view.

A display device according to one or more embodiments includes a first light-emitting element located in a first pixel area, a first nanostructure array located in the first pixel area on the first light-emitting element, where the first nanostructure array includes first nanostructures repeatedly arranged along a first direction and a second direction crossing the first direction, a second light-emitting element located in a second pixel area spaced apart from the first pixel area in a plan view, and a second nanostructure array located in the second pixel area on the second light-emitting element, where the second nanostructure array includes second nanostructures repeatedly arranged along the first direction and the second direction.

In one or more embodiments, inclination angles of the first nanostructures with respect to the first direction may change along the first direction.

In one or more embodiments, inclination angles of the second nanostructures with respect to the first direction may change along the first direction.

In one or more embodiments, the inclination angles of the first nanostructures with respect to the first direction may change along the second direction and the inclination angles of the second nanostructures with respect to the first direction may change along the second direction.

In one or more embodiments, a separation distance between two adjacent first nanostructures of the first nanostructures and a separation distance between two adjacent second nanostructures of the second nanostructures may be different from each other.

In one or more embodiments, the first pixel area may emit red light, the second pixel area may emit green light, and the separation distance between the two adjacent first nanostructures of the first nanostructures may be greater than the separation distance between the two adjacent second nanostructures of the second nanostructures.

In one or more embodiments, each of the first nanostructures may have an elliptical pillar shape, lengths of a major axis of the first nanostructures may change along the first direction, each of the second nanostructures may have an elliptical pillar shape, and lengths of a major axis of the second nanostructures may change along the first direction.

In one or more embodiments, the display device may further include a first refractive layer covering the first nanostructures, a second refractive layer covering the second nanostructures, and a microlens layer covering the first refractive layer and the second refractive layer.

An electronic device according to one or more embodiments includes a first light-emitting element located in a first pixel area, a first nanostructure array located in the first pixel area on the first light-emitting element, where the first nanostructure array includes first nanostructures repeatedly arranged along a first direction and a second direction crossing the first direction, a second light-emitting element located in a second pixel area spaced apart from the first pixel area in a plan view, a second nanostructure array located in the second pixel area on the second light-emitting element, where the second nanostructure array includes second nanostructures repeatedly arranged along the first direction and the second direction and a memory configured to store data information.

In one or more embodiments, lengths of the first nanostructures in a horizontal direction thereof may change along the first direction.

In one or more embodiments, lengths of the second nanostructures in a horizontal direction thereof may change along the first direction.

A display device according to one or more embodiments includes a first light-emitting element located in a first pixel area, a first nanostructure array located in the first pixel area on the first light-emitting element and including first nanostructures repeatedly arranged along a first direction and a second direction crossing the first direction, a second light-emitting element located in a second pixel area spaced apart from the first pixel area in a plan view, and a second nanostructure array located in the second pixel area on the second light-emitting element and including second nanostructures repeatedly arranged along the first direction and the second direction. In such embodiments, lengths of the first nanostructures in a horizontal direction thereof may change along the first direction, and lengths of the second nanostructures in a horizontal direction thereof may change along the first direction. In such embodiments, inclination angles of the first nanostructures with respect to the first direction may change along the first direction and inclination angles of the second nanostructures with respect to the first direction may change along the first direction.

Accordingly, reflection of external light incident on the display device may be blocked and light emitted from the light-emitting element may be condensed at a same time. Accordingly, a polarizing plate and/or the like may be omitted, thereby reducing a manufacturing cost of the display device. In addition, as the polarizing plate and/or the like may be omitted, a thickness of the display device may be reduced. Accordingly, a structure suitable for a display device including a foldable area such as a foldable display device may be provided.

### BRIEF DESCRIPTION OF THE DRAWINGS

Illustrative, non-limiting embodiments will be more clearly understood from the following detailed description in conjunction with the accompanying drawings.

FIG. 1 is a perspective view illustrating a display device according to one or more embodiments.

FIG. 2 is a cross-sectional view illustrating the display device of FIG. 1.

FIG. 3 is a cross-sectional view illustrating an example of the display device of FIG. 1 taken along line I-I′.

FIG. 4 is a schematic plan view illustrating an example of a partial area of the display device of FIG. 1.

FIG. 5 is a perspective view illustrating a first nanostructure array included in the display device of FIG. 4.

FIG. 6 is a perspective view illustrating a first nanostructure, a second nanostructure, and a third nanostructure included in the display device of FIG. 4.

FIG. 7 is a cross-sectional view illustrating a path of light emitted from a light-emitting element of the display device of FIG. 3.

FIG. 8 is a cross-sectional view illustrating a path of external light incident on the display device of FIG. 3.

FIG. 9 is a schematic plan view illustrating an example of a partial area of the display device of FIG. 1.

FIG. 10 is a perspective view illustrating a first nanostructure array included in the display device of FIG. 9.

FIG. 11 is a perspective view illustrating a first nanostructure, a second nanostructure, and a third nanostructure included in the display device of FIG. 9.

FIG. 12 is a plan view illustrating an example of a first nanostructure array included in the display device of FIG. 4.

FIG. 13 is a cross-sectional view illustrating an example of the display device of FIG. 1 taken along line I-I′.

FIG. 14 is a cross-sectional view illustrating an example of the display device of FIG. 1 taken along line I-I′.

FIG. 15 is a cross-sectional view illustrating a portion of the display device of FIG. 14.

FIG. 16 is a plan view schematically illustrating a partial area of the display device of FIG. 14.

FIG. 17 is a perspective view illustrating a first nanostructure array included in the display device of FIG. 16.

FIG. 18 is a block diagram illustrating an electronic device according to one or more embodiments.

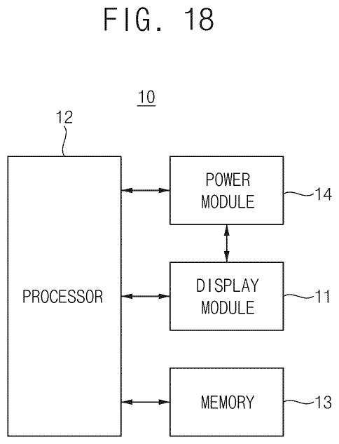

FIG. 19 is a schematic diagram of an electronic device according to various embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, display devices in accordance with embodiments will be described in greater detail with reference to the accompanying drawings. The same reference numerals are used for the same components in the drawings, and any repetitive detailed descriptions of the same components will be omitted or simplified.

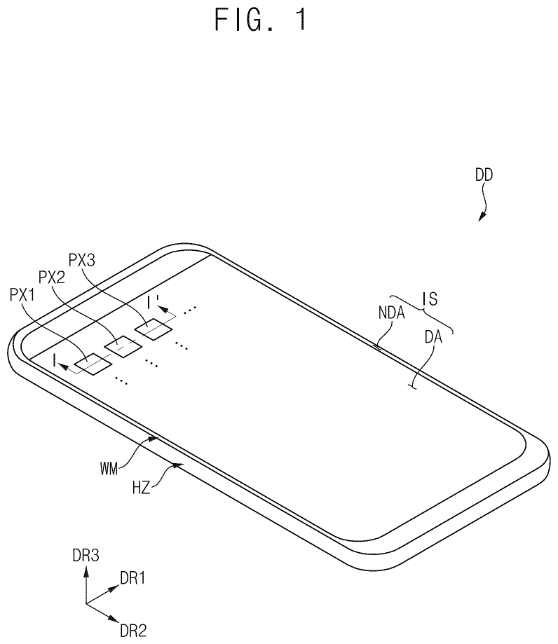

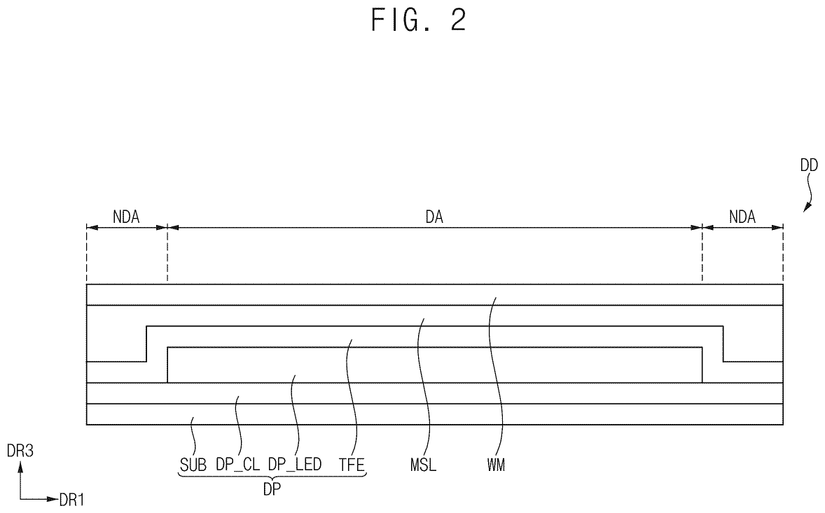

FIG. 1 is a perspective view illustrating a display device according to one or more embodiments. FIG. 2 is a cross-sectional view illustrating the display device of FIG. 1.

Referring to FIG. 1, a display device DD according to one or more embodiments may be a device activated by an electrical signal. For example, the display device DD may be a small display device used in small electronic devices such as smartphones, mobile phones, smart watches, game consoles, cameras, and/or the like. However, this disclosure is not limited thereto, and the display device DD may be a medium to large-sized display device used in medium to large-sized electronic devices such as laptops, tablet computers, personal computers (PCs), televisions, computer monitors, vehicle monitors, external billboards, and/or the like.

An upper surface of the display device DD may be defined as a display surface IS. The display surface IS may be a surface parallel to a plane formed by a first direction DR1 and a second direction DR2 crossing the first direction DR1. An image generated by the display device DD may be provided to a user through the display surface IS.

The display device DD may include a display area DA and a non-display area NDA. In an embodiment, for example, the display surface IS may be divided into the display area DA and the non-display area NDA. The display area DA may be an area in which an image is displayed. In an embodiment, for example, the display area DA may be an area that generates light or adjusts transmittance of light provided from an external light source to display an image. The non-display area NDA may surround at least a portion of the display area DA. In one or more embodiments, the non-display area NDA may be an area in which an image is not displayed. However, this disclosure is not limited thereto, and an image may be displayed in a portion of the non-display area NDA. The non-display area NDA may include a plurality of drivers.

A plurality of pixel areas may be disposed in the display area DA. In an embodiment, for example, a first pixel area PX1, a second pixel area PX2, and a third pixel area PX3 may be disposed in the display area DA. Each of the first pixel area PX1, the second pixel area PX2, and the third pixel area PX3 may emit light. In one or more embodiments, the first pixel area PX1, the second pixel area PX2, and the third pixel area PX3 may emit light having different wavelengths. In an embodiment, for example, the first pixel area PX1 may emit red light, the second pixel area PX2 may emit green light, and the third pixel area PX3 may emit blue light, but this disclosure is not limited thereto. The first pixel area PX1, the second pixel area PX2, and the third pixel area PX3 may be spaced apart from each other in a plan view. In an embodiment, for example, the second pixel area PX2 may be spaced apart from the first pixel area PX1 in the first direction DR1, and the third pixel area PX3 may be spaced apart from the second pixel area PX2 in the first direction DR1, but this disclosure is not limited thereto. The plurality of pixel areas may be generally disposed in the display area DA. In an embodiment, for example, the plurality of pixel areas may be generally disposed in the display area DA along the first direction DR1 and the second direction DR2. As each of the plurality of pixel areas emits light in the display area DA, the display area DA may display an image.

The display device DD may include a housing HZ and a window WM. The housing HZ and the window WM may be coupled to constitute an external appearance of the display device DD. The housing HZ may protect components included in the display device DD from external impact. The housing HZ may include a material having relatively high rigidity. In an embodiment, for example, the housing HZ may include glass, plastic, metal, and/or the like. These materials may be used alone or in combination with each other. In an embodiment, for example, the window WM may be an ultra thin glass or polyimide film, but this disclosure is not limited thereto.

In one or more embodiments, the first direction DR1 and the second direction DR2 crossing the first direction DR1 may be defined. In an embodiment, for example, the second direction DR2 may be substantially perpendicular to the first direction DR1. However, this disclosure is not limited thereto, and the second direction DR2 may form an acute angle or an obtuse angle with the first direction DR1. In addition, a third direction DR3 crossing a plane formed by the first direction DR1 and the second direction DR2 may be defined. In an embodiment, for example, the third direction DR3 may be substantially perpendicular to the plane formed by the first direction DR1 and the second directions DR2. However, this disclosure is not limited thereto, and the third direction DR3 may form an acute angle or an obtuse angle with the plane formed by the first direction DR1 and the second direction DR2. In an embodiment, for example, the third direction DR3 may be a thickness direction of the display device DD.

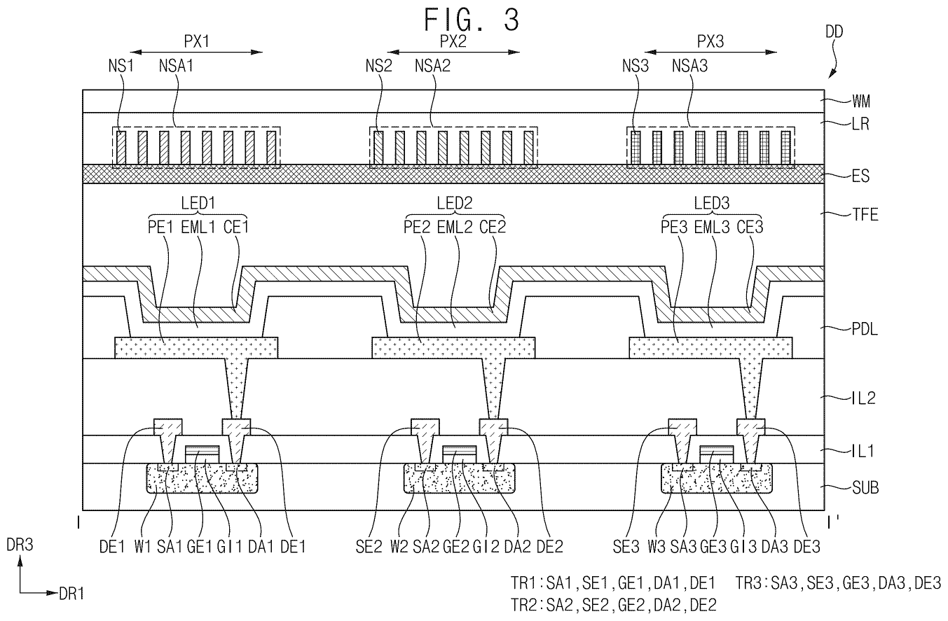

Referring to FIG. 2, an embodiment of the display device DD may include a display panel DP, a metasurface layer MSL, and the window WM. The display panel DP may display an image according to an electrical signal. In an embodiment, for example, the plurality of pixel areas may be disposed in the display panel DP. The metasurface layer MSL may be disposed on the display panel DP. The metasurface layer MSL may include nanostructure arrays. In an embodiment, for example, the metasurface layer MSL may include a first nanostructure array (e.g., a first nanostructure array NSA1 of FIG. 3), a second nanostructure array (e.g., a second nanostructure array NSA2 of FIG. 3), and a third nanostructure array (e.g., a third nanostructure array NSA3 of FIG. 3). The window WM may be disposed on the metasurface layer MSL.

The display panel DP may be an organic light-emitting display panel, an inorganic light-emitting display panel, or a quantum dot display panel, but this disclosure is not limited thereto. Hereinafter, for convenience of description, embodiments where the display panel DP is the organic light-emitting display panel will be mainly described.

In one or more embodiments, the display panel DP may include a substrate SUB, a circuit layer DP_CL, a element layer DP_LED, and an encapsulation layer TFE. The substrate SUB may be a base layer of the display panel DP. The circuit layer DP_CL may be disposed on the substrate SUB. The circuit layer DP_CL may include a circuit element. In an embodiment, for example, the circuit layer DP_CL may include a first transistor (e.g., a first transistor TR1 of FIG. 3), a second transistor (e.g., a second transistor TR2 of FIG. 3), and a third transistor (e.g., a third transistor TR3 of FIG. 3). The element layer DP_LED may be disposed on the circuit layer DP_CL. In an embodiment, for example, the element layer DP_LED may include a first light-emitting element (e.g., a first light-emitting element LED1 of FIG. 3), a second light-emitting element (e.g., a second light-emitting element LED2 of FIG. 3), and a third light-emitting element (e.g., a third light-emitting element LED3 of FIG. 3). The encapsulation layer TFE may be disposed on the element layer DP_LED to seal the element layer DP_LED.

FIG. 3 is a cross-sectional view illustrating an example of the display device of FIG. 1 taken along line I-I′.

Referring to FIG. 3, an embodiment of the display device DD may include the substrate SUB, a first insulating layer IL1, a second insulating layer IL2, a first transistor TR1, a second transistor TR2, a third transistor TR3, a first gate insulating layer GI1, a second gate insulating layer GI2, a third gate insulating layer GI3, a first light-emitting element LED1, a second light-emitting element LED2, a third light-emitting element LED3, a pixel defining layer PDL, the encapsulation layer TFE, an etch stopper ES, a first nanostructure array NSA1, a second nanostructure array NSA2, a third nanostructure array NSA3, a low-refractive index layer LR, and the window WM.

The first transistor TR1 may include a first contact area SA1, a first contact electrode SE1, a first gate electrode GE1, a second contact area DA1, and a second contact electrode DE1. The second transistor TR2 may include a third contact area SA2, a third contact electrode SE2, a second gate electrode GE2, a fourth contact area DA2, and a fourth contact electrode DE2. The third transistor TR3 may include a fifth contact area SA3, a fifth contact electrode SE3, a third gate electrode GE3, a sixth contact area DA3, and a sixth contact electrode DE3.

The first light-emitting element LED1 may include a first pixel electrode PE1, a first light-emitting layer EML1, and a first common electrode CE1. The second light-emitting element LED2 may include a second pixel electrode PE2, a second light-emitting layer EML2, and a second common electrode CE2. The third light-emitting element LED3 may include a third pixel electrode PE3, a third light-emitting layer EML3, and a third common electrode CE3.

The substrate SUB may be a base layer of the display device DD. In one or more embodiments, the substrate SUB may be a silicon substrate. In an embodiment, for example, the substrate SUB may be a P-type silicon substrate or an N-type silicon substrate. In this case, P may denote a hole, and N may denote electron. The substrate SUB may include a first well area W1, a second well area W2, and a third well area W3. The first well area W1 may be a P-well or an N-well depending on type of the first transistor TR1 and type of the substrate SUB. In addition, the second well area W2 may be a P-well or an N-well depending on type of the second transistor TR2 and the type of the substrate SUB. In addition, the third well area W3 may be a P-well or an N-well depending on type of the third transistor TR3 and the substrate SUB.

The substrate SUB may include the first contact area SA1 and the second contact area DA1. In an embodiment, for example, the first contact area SA1 and the second contact area DA1 may be an N-source area and an N-drain area, respectively. However, this disclosure is not limited thereto, and the first contact area SA1 and the second contact area DA1 may be a P-source area and a P-drain area, respectively.

The substrate SUB may further include the third contact area SA2 and the fourth contact area DA2. In an embodiment, for example, the third contact area SA2 and the fourth contact area DA2 may be an N-source area and an N-drain area, respectively. However, this disclosure is not limited thereto, and the third contact area SA2 and the fourth contact area DA2 may be a P-source area and a P-drain area, respectively.

The substrate SUB may further include a fifth contact area SA3 and a sixth contact area DA3. In an embodiment, for example, the fifth contact area SA3 and the sixth contact area DA3 may be an N-source area and an N-drain area, respectively. However, this disclosure is not limited thereto, and the fifth contact area SA3 and the sixth contact area DA3 may be a P-source area and a P-drain area, respectively.

However, this disclosure in not limited thereto, in one/or more embodiments, the substrate SUB may include or be formed of a transparent resin substrate. Example of the transparent resin substrate may include a polyimide substrate. In this case, the polyimide substrate may include a first organic layer, a first barrier layer, a second organic layer, and/or the like. In another embodiment, the substrate SUB may include a quartz substrate (e.g. a synthetic quartz substrate, a fluorine-doped quartz substrate), a calcium fluoride substrate, a sodalime glass substrate, a non-alkali glass substrate, and/or the like. These materials may be used alone or in combination with each other. In such an embodiment, the display device DD may further include a first active pattern disposed in the first pixel area PX1 on the substrate SUB, a second active pattern disposed in the second pixel area PX2, and a third active pattern disposed in the third pixel area PX3.

The first gate insulating layer GI1, the second gate insulating layer GI2, and the third gate insulating layer GI3 may be disposed on the substrate SUB. The first gate insulating layer GI1 may at least partially overlap the first well area W1 in a plan view (or when viewed in the third direction DR3). In addition, the second gate insulating layer GI2 may at least partially overlap the second well area W2 in a plan view. In addition, the third gate insulating layer GI3 may at least partially overlap the third well area W3 in a plan view.

In an embodiment, for example, each of the first gate insulating layer GI1, the second gate insulating layer GI2, and the third gate insulating layer GI3 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first gate electrode GE1 may be disposed on the first gate insulating layer GI1. In an embodiment, for example, the first gate electrode GE1 may overlap the first gate insulating layer GI1 in a plan view. The second gate electrode GE2 may be disposed on the second gate insulating layer GI2. In an embodiment, for example, the second gate electrode GE2 may overlap the second gate insulating layer GI2 in a plan view. The third gate electrode GE3 may be disposed on the third gate insulating layer GI3. In an embodiment, for example, the third gate electrode GE3 may overlap the third gate insulating layer GI3 in a plan view.

In an embodiment, for example, each of the first gate electrode GE1, the second gate electrode GE2, and the third gate electrode GE3 may include a metal, an alloy, a metal nitride, a conductive metal oxide, a transparent conductive material, and/or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The first insulating layer IL1 may be disposed on the substrate SUB. The first insulating layer IL1 may cover at least a portion of each of the first gate electrode GE1, the second gate electrode GE2, the third gate electrode GE3, the first gate insulating layer GI1, the second gate insulating layer GI2, and the third gate insulating layer GI3.

In an embodiment, for example, the first insulating layer may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first contact electrode SE1, the second contact electrode DE1, the third contact electrode SE2, the fourth contact electrode DE2, the fifth contact electrode SE3 and the sixth contact electrode DE3 may be disposed on the first insulating layer IL1. The first contact electrode SE1 may be connected to the first contact area SA1 through a contact hole penetrating (or defined through) the first insulating layer IL1. In addition, the second contact electrode DE1 may be connected to the second contact area DA1 through a contact hole penetrating (or defined through) the first insulating layer IL1. In addition, the third contact electrode SE2 may be connected to the third contact area SA2 through a contact hole penetrating (or defined through) the first insulating layer IL1. In addition, the fourth contact electrode DE2 may be connected to the fourth contact area DA2 through a contact hole penetrating (or defined through) the first insulating layer IL1. In addition, the fifth contact electrode SE3 may be connected to the fifth contact area SA3 through a contact hole penetrating (or defined through) the first insulating layer IL1. In addition, the sixth contact electrode DE3 may be connected to the sixth contact area DA3 through a contact hole penetrating (or defined through) the first insulating layer IL1.

Each of the first contact electrode SE1, the second contact electrode DE1, the third contact electrode SE2, the fourth contact electrode DE2, the fifth contact electrode SE3 and the sixth contact electrode DE3 may include a metal, an alloy, a metal nitride, a conductive metal oxide, a transparent conductive material, and/or the like. These materials may be used alone or in combination with each other.

Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

In an embodiment, for example, the first transistor TR1, the second transistor TR2, and the third transistor TR3 may be disposed on the substrate SUB. The second transistor TR2 may be spaced apart from the first transistor TR1 in a plan view. In an embodiment, for example, the second transistor TR2 may be spaced apart from the first transistor TR1 in the first direction DR1. The third transistor TR3 may be spaced apart from the second transistor TR2 in a plan view. In an embodiment, for example, the third transistor TR3 may be spaced apart from the second transistor TR2 in the first direction DR1.

The second insulating layer IL2 may be disposed on the first insulating layer IL1. The second insulating layer IL2 may cover the first contact electrode SE1, the second contact electrode DE1, the third contact electrode SE2, the fourth contact electrode DE2, the fifth contact electrode SE3 and the sixth contact electrode DE3.

In an embodiment, for example, the second insulating layer IL2 may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first light-emitting element LED1, the second light-emitting element LED2, and the third light-emitting element LED3 may be disposed on the second insulating layer IL2. The first light-emitting element LED1 may be disposed in the first pixel area PX1, the second light-emitting element LED2 may be disposed in the second pixel area PX2, and the third light-emitting element LED3 may be disposed in the third pixel area PX3.

In an embodiment, for example, the first pixel electrode PE1, the second pixel electrode PE2, and the third pixel electrode PE3 may be disposed on the second insulating layer IL2. The first pixel electrode PE1 may be disposed in the first pixel area PX1, the second pixel electrode PE2 may be disposed in the second pixel area PX2, and the third pixel electrode PE3 may be disposed in the third pixel area PX3.

The first pixel electrode PE1 may be connected to the second contact electrode DE1 through a contact hole penetrating (or defined through) the second insulating layer IL2. In addition, the second pixel electrode PE2 may be connected to the fourth contact electrode DE2 through a contact hole penetrating (or defined through) the second insulating layer IL2. In addition, the third pixel electrode PE3 may be connected to the sixth contact electrode DE3 through a contact hole penetrating (or defined through) the second insulating layer IL2.

In an embodiment, for example, each of the first pixel electrode PE1, the second pixel electrode PE2, and the third pixel electrode PE3 may include a metal, an alloy, a metal nitride, a conductive metal oxide, a transparent conductive material, and/or the like. These materials may be used alone or in combination with each other. In one or more embodiments, each of the first pixel electrode PE1, the second pixel electrode PE2, and the third pixel electrode PE3 may have a stacked structure including ITO/Ag/ITO, but this disclosure is not limited thereto. The first pixel electrode PE1 may operate as an anode of the first light-emitting element LED1, the second pixel electrode PE2 may operate as an anode of the second light-emitting element LED2, and the third pixel electrode PE3 may operate as an anode of the third light-emitting element LED3.

The pixel defining layer PDL may be disposed on the second insulating layer IL2. The pixel defining layer PDL may cover a side portion of the first pixel electrode PE1. In an embodiment, for example, an opening exposing a portion of an upper surface of the first pixel electrode PE1 may be defined in the pixel defining layer PDL. In addition, the pixel defining layer PDL may cover a side portion of the second pixel electrode PE2. In an embodiment, for example, an opening exposing a portion of an upper surface of the second pixel electrode PE2 may be defined in the pixel defining layer PDL. In addition, the pixel defining layer PDL may cover a side portion of the third pixel electrode PE3. In an embodiment, for example, an opening exposing a portion of an upper surface of the third pixel electrode PE3 may be defined in the pixel defining layer PDL.

In an embodiment, for example, the pixel defining layer PDL may include an inorganic material or an organic material. In one or more embodiments, the pixel defining layer PDL may include an organic material such as an epoxy resin, a siloxane resin, and/or the like. These materials may be used alone or in combination with each other. In one or more embodiments, the pixel defining layer PDL may further include a light-blocking material including a black pigment, a black dye, and/or the like.

The first light-emitting layer EML1 may be disposed on the first pixel electrode PE1. The first light-emitting layer EML1 may be disposed in the first pixel area PX1. In addition, the second light-emitting layer EML2 may be disposed on the second pixel electrode PE2. The second light-emitting layer EML2 may be disposed in the second pixel area PX2. In addition, the third light-emitting layer EML3 may be disposed on the third pixel electrode PE3. The third light-emitting layer EML3 may be disposed in the third pixel area PX3. In one or more embodiments, the first light-emitting layer EML1, the second light-emitting layer EML2, and the third light-emitting layer EML3 may be integrally formed with each other as a single unitary indivisible part. In an embodiment, for example, the first light-emitting layer EML1 may be connected to the second light-emitting layer EML2, and the second light-emitting layer EML2 may be connected to the third light-emitting layer EML3. However, this disclosure is not limited thereto, and in one or more embodiments, the first light-emitting layer EML1 may be separated from the second light-emitting layer EML2, and the second light-emitting layer EML2 may be separated from the third light-emitting layer EML3. In an embodiment, for example, each of the first light-emitting layer EML1, the second light-emitting layer EML2, and the third light-emitting layer EML3 may include an organic material that emits light of a selected color.

The first common electrode CE1 may be disposed on the first light-emitting layer EML1. The first common electrode CE1 may be disposed in the first pixel area PX1. In addition, the second common electrode CE2 may be disposed on the second light-emitting layer EML2. The second common electrode CE2 may be disposed in the second pixel area PX2. In addition, the third common electrode CE3 may be disposed on the third light-emitting layer EML3. The third common electrode CE3 may be disposed in the third pixel area PX3. In one or more embodiments, the first common electrode CE1, the second common electrode CE2, and the third common electrode CE3 may be integrally formed with each other as a single unitary indivisible part. In an embodiment, for example, the first common electrode CE1 may be connected to the second common electrode CE2, and the second common electrode CE2 may be connected to the third common electrode CE3. However, this disclosure is not limited thereto, and in one or more embodiments, the first common electrode CE1 may be separated from the second common electrode CE2, and the second common electrode CE2 may be separated from the third common electrode CE3.

In an embodiment, for example, each of the first common electrode CE1, the second common electrode CE2, and the third common electrode CE3 may include a metal, an alloy, a metal nitride, a conductive metal oxide, a transparent conductive material, and/or the like. These materials may be used alone or in combination with each other. The first common electrode CE1 may operate as a cathode of the first light-emitting element LED1, the second common electrode CE2 may operate as a cathode of the second light-emitting element LED2, and the third common electrode CE3 may operate as a cathode of the third light-emitting element LED3.

The encapsulation layer TFE may be disposed on the first common electrode CE1, the second common electrode CE2, and the third common electrode CE3. The encapsulation layer TFE may effectively prevent impurities, moisture, and/or the like from penetrating into the first light-emitting element LED1, the second light-emitting element LED2, and the third light-emitting element LED3 from an outside of the display device DD.

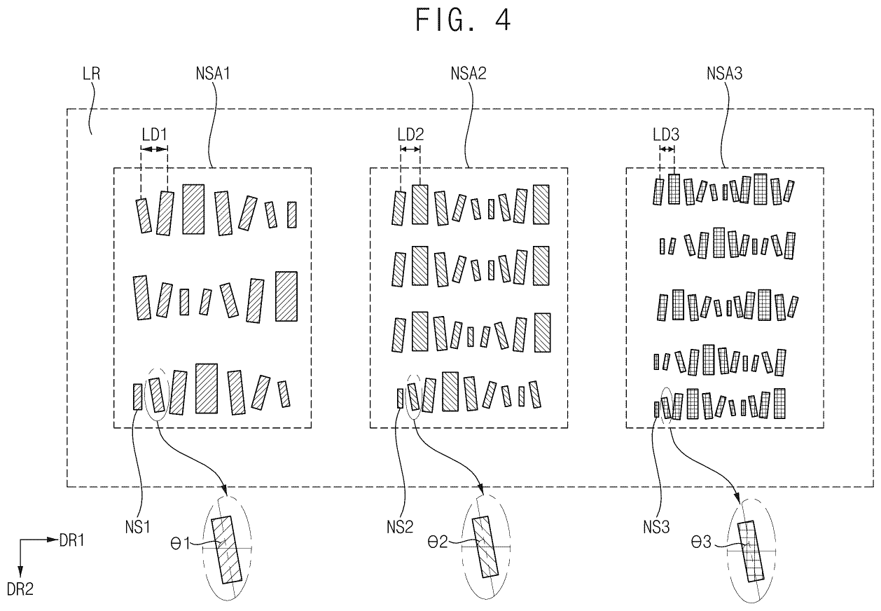

The first nanostructure array NSA1, the second nanostructure array NSA2, and the third nanostructure array NSA3 may be disposed on the encapsulation layer TFE. The first nanostructure array NSA1 may be disposed in the first pixel area PX1. The second nanostructure array NSA2 may be disposed in the second pixel area PX2. The third nanostructure array NSA3 may be disposed in the third pixel area PX3. The first nanostructure array NSA1 may include first nanostructures NS1. In an embodiment, for example, the first nanostructure array NSA1 may be a set of the first nanostructures NS1. The second nanostructure array NSA2 may include second nanostructures NS2. In an embodiment, for example, the second nanostructure array NSA2 may be a set of the second nanostructures NS2. The third nanostructure array NSA3 may include third nanostructures NS3. In an embodiment, for example, the third nanostructure array NSA3 may be a set of the third nanostructures NS3. The first nanostructure array NSA1, the second nanostructure array NSA2, and the third nanostructure array NSA3 will be described in detail with reference to FIGS. 4, 5, and 6.

The etch stopper ES may be disposed under the first nanostructure array NSA1, the second nanostructure array NSA2, and the third nanostructure array NSA3. In an embodiment, for example, the etch stopper ES may be disposed on the encapsulation layer TFE. The etch stopper ES may effectively prevent a portion of the encapsulation layer TFE from being etched when the first nanostructure array NSA1, the second nanostructure array NSA2, and the third nanostructure array NSA3 are formed by an etching process. In an embodiment, for example, the etch stopper ES may include gallium oxide, indium zinc oxide, indium tin oxide, hafnium oxide, titanium oxide, zirconium oxide, and/or the like. These materials may be used alone or in combination with each other. The etch stopper ES may be omitted.

The low-refractive layer LR may be disposed on the etch stopper ES. The low-refractive layer LR may cover the first nanostructure array NSA1, the second nanostructure array NSA2, and the third nanostructure array NSA3. In one or more embodiments, the low-refractive layer LR may include an organic material. In an embodiment, for example, the low-refractive layer LR may include acrylic resin, polyimide resin, polyamide resin, and/or the like. These materials may be used alone or in combination with each other. However, this disclosure is not limited thereto. In one or more embodiments, the low-refractive layer LR may include an inorganic material such as silicon nitride, aluminum nitride, silicon oxynitride, hafnium nitride, titanium nitride, and/or the like. These materials may be used alone or in combination with each other. In one or more embodiments, a refractive index of the low-refractive layer LR may be equal to or greater than about 1.45 and equal to or less than about 1.5, but this disclosure is not limited thereto.

The window WM may be disposed on the low-refractive index layer LR.

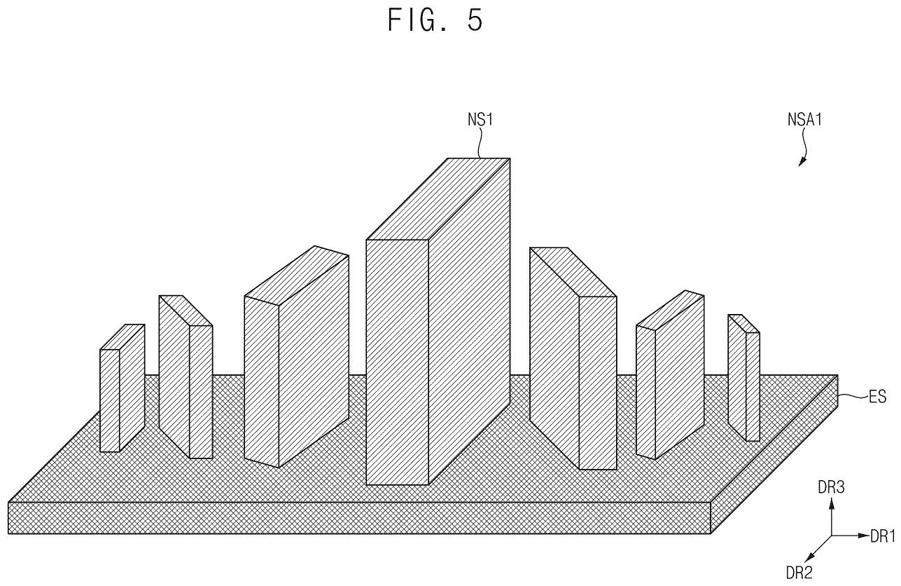

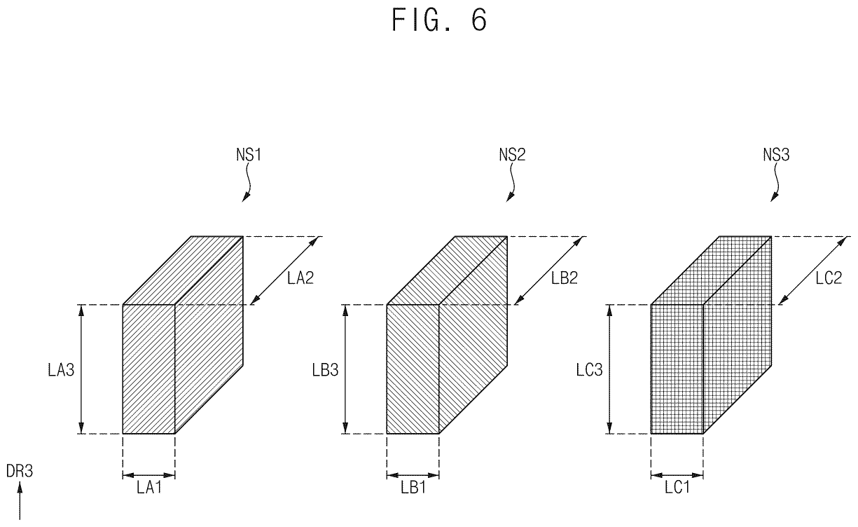

FIG. 4 is a schematic plan view illustrating an example of a partial area of the display device of FIG. 1. FIG. 5 is a perspective view illustrating a first nanostructure array included in the display device of FIG. 4. FIG. 6 is a perspective view illustrating a first nanostructure, a second nanostructure, and a third nanostructure included in the display device of FIG. 4.

In detail, FIG. 4 may be a plan view illustrating the first nanostructure array NSA1, the second nanostructure array NSA2, the third nanostructure array NSA3, and the low-refractive index layer LR. In addition, FIG. 6 may be an enlarged perspective view of each of the first nanostructures NS1, the second nanostructures NS2, and the third nanostructures NS3.

Referring to FIGS. 4 and 5, in an embodiment, the first nanostructure array NS1 may include first nanostructures NS1 as described above. The first nanostructures NS1 may be repeatedly arranged along the first direction DR1 and the second direction DR2. In an embodiment, for example, the first nanostructures NS1 may be repeatedly arranged in the first pixel area (e.g., the first pixel area PX1 of FIG. 3) along the first direction DR1 and the second direction DR2. The first nanostructures NS1 may be spaced apart from each other in a plan view.

In one or more embodiments, a degree of inclination of the first nanostructures NS1 in a plan view may change depending on positions of the first nanostructures NS1 in a plan view. In an embodiment, for example, a degree of inclination of adjacent first nanostructures of the first nanostructures NS1 in a plan view may be different from each other. In an embodiment, for example, as illustrated in FIG. 4, an inclination angle θ1 of the first nanostructures NS1 (or an inclination angle θ1 of a longitudinal axis of the first nanostructures NS1) with respect to the first direction DR1 may be different depending on positions of the first nanostructures NS1 in a plan view. In an embodiment, for example, the inclination angle θ1 of the first nanostructures NS1 with respect to the first direction DR1 may change along the first direction DR1. In an embodiment, for example, inclination angles with respect to the first direction DR1 of two adjacent first nanostructures adjacent in the first direction DR1 of the first nanostructures NS1 may be different from each other. In an embodiment, for example, the first nanostructure array NSA1 may include first nanostructures NS1 in which the inclination angle θ1 with respect to the first direction DR1 changes at a constant period (or a constant amount of angle change) along the first direction DR1. In one or more embodiments, the inclination angle θ1 of the first nanostructures NS1 with respect to the first direction DR1 may also change along the second direction DR2. In an embodiment, for example, inclination angles with respect to the first direction DR1 of two adjacent first nanostructures adjacent in the second direction DR2 of the first nanostructures NS1 may be different from each other. In an embodiment, for example, the first nanostructure array NSA1 may include first nanostructures NS1 in which the inclination angle θ1 with respect to the first direction DR1 changes at a constant period along the first direction DR1 and the second direction DR2. In one or more embodiments, the inclination angle θ1 of the first nanostructures NS1 with respect to the first direction DR1 may change at a first period along the first direction DR1, and the inclination angle θ1 of the first nanostructures NS1 with respect to the first direction DR1 may change at a second period along the second direction DR2, and the first period and the second period may be different from each other. However, this disclosure is not limited thereto, and the first period and the second period may be substantially the same as each other. In one or more embodiments, the inclination angle θ1 of the first nanostructures NS1 with respect to the first direction DR1 may gradually change along the first direction DR1 and the second direction DR2.

The degree of inclination of the first nanostructures NS1 in a plan view is described as the inclination angle θ1 with respect to the first direction DR1, but this disclosure is not limited thereto, and the degree of inclination of the first nanostructures NS1 in a plan view may be understood as an inclination angle of the first nanostructures NS1 with respect to the second direction DR2.

As described above, the second nanostructure array NSA2 may include second nanostructures NS2. The second nanostructures NS2 may be repeatedly arranged along the first direction DR1 and the second direction DR2. In an embodiment, for example, the second nanostructures NS2 may be repeatedly arranged along the first direction DR1 and the second direction DR2 in the second pixel area (e.g., the second pixel area PX2 of FIG. 3). The second nanostructures NS2 may be spaced apart from each other in a plan view.

In one or more embodiments, a degree of inclination of the second nanostructures NS2 in a plan view may change depending on positions of the second nanostructures NS2 in a plan view. In an embodiment, for example, a degree of inclination of adjacent second nanostructures of the second nanostructures NS2 in a plan view may be different from each other. In an embodiment, for example, as illustrated in FIG. 4, an inclination angle θ2 of the second nanostructures NS2 with respect to the first direction DR1 may be different depending on positions of the second nanostructures NS2 in a plan view. In an embodiment, for example, the inclination angle θ2 of the second nanostructures NS2 with respect to the first direction DR1 may change along the first direction DR1. In an embodiment, for example, inclination angles with respect to the first direction DR1 of two adjacent second nanostructures adjacent in the first direction DR1 of the second nanostructures NS2 may be different from each other. In an embodiment, for example, the second nanostructure array NSA2 may include second nanostructures NS2 in which the inclination angle θ2 with respect to the first direction DR1 changes at a constant period along the first direction DR1. In one or more embodiments, the inclination angle θ2 of the second nanostructures NS2 with respect to the first direction DR1 may also change along the second direction DR2. In an embodiment, for example, inclination angles with respect to the first direction DR1 of two adjacent second nanostructures adjacent in the second direction DR2 of the second nanostructures NS2 may be different from each other. In an embodiment, for example, the second nanostructure array NSA2 may include second nanostructures NS2 in which the inclination angle θ2 with respect to the first direction DR1 changes at a constant period along the first direction DR1 and the second direction DR2. In one or more embodiments, the inclination angle θ2 of the second nanostructures NS2 with respect to the first direction DR1 may change at a third period along the first direction DR1, and the inclination angle θ2 of the second nanostructures NS2 with respect to the first direction DR1 may change at a fourth period along the second direction DR2, and the third period and the fourth period may be different from each other. However, this disclosure is not limited thereto, and the third period and the fourth period may be substantially the same as each other. In one or more embodiments, the inclination angle θ2 of the second nanostructures NS2 with respect to the first direction DR1 may gradually change along the first direction DR1 and the second direction DR2.

The degree of inclination of the second nanostructures NS2 in a plan view is described as the inclination angle θ2 with respect to the first direction DR1, but this disclosure is not limited thereto, and the degree of inclination of the second nanostructures NS2 in a plan view may be understood as an inclination angle of the second nanostructures NS2 with respect to the second direction DR2.

As described above, the third nanostructure array NSA3 may include third nanostructures NS3. The third nanostructures NS3 may be repeatedly arranged along the first direction DR1 and the second direction DR2. In an embodiment, for example, the third nanostructures NS3 may be repeatedly arranged along the first direction DR1 and the second direction DR2 in the third pixel area (e.g., the third pixel area PX3 of FIG. 3). The third nanostructures NS3 may be spaced apart from each other in a plan view.

In one or more embodiments, a degree of inclination of third nanostructures NS3 in a plan view may change depending on positions of third nanostructures NS3 in a plan view. In an embodiment, for example, a degree of inclination of adjacent third nanostructures of the third nanostructures NS3 in a plan view may be different from each other. In an embodiment, for example, as illustrated in FIG. 4, an inclination angle θ3 of the third nanostructures NS3 with respect to the first direction DR1 may be different depending on positions of the third nanostructures NS3 in a plan view. In an embodiment, for example, the inclination angle θ3 of the third nanostructures NS3 with respect to the first direction DR1 may change along the first direction DR1. In an embodiment, for example, inclination angles with respect to the first direction DR1 of two adjacent third nanostructures adjacent in the first direction DR1 of the third nanostructures NS3 may be different from each other. In an embodiment, for example, the third nanostructure array NSA3 may include third nanostructures NS3 in which the inclination angle θ3 with respect to the first direction DR1 changes at a constant period along the first direction DR1. In one or more embodiments, the inclination angle θ3 of the third nanostructures NS3 with respect to the first direction DR1 may also change along the second direction DR2. In an embodiment, for example, inclination angles with respect to the first direction DR1 of two adjacent third nanostructures adjacent in the second direction DR2 of the third nanostructures NS3 may be different from each other. In an embodiment, for example, the third nanostructure array NSA3 may include third nanostructures NS3 in which the inclination angle θ3 with respect to the first direction DR1 changes at a constant period along the first direction DR1 and the second direction DR2. In one or more embodiments, the inclination angle θ3 of the second third nanostructures NS3 with respect to the first direction DR1 may change at a fifth period along the first direction DR1, and the inclination angle θ3 of the third nanostructures NS3 with respect to the first direction DR1 may change at a sixth period along the second direction DR2, and the fifth period and the sixth period may be different from each other. However, this disclosure is not limited thereto, and the fifth period and the sixth period may be substantially the same as each other. In one or more embodiments, the inclination angle θ3 of the third nanostructures NS3 with respect to the first direction DR1 may gradually change along the first direction DR1 and the second direction DR2.

The degree of inclination of the third nanostructures NS3 in a plan view is described as the inclination angle θ3 with respect to the first direction DR1, but this disclosure is not limited thereto, and the degree of inclination of the third nanostructures NS3 in a plan view may be understood as an inclination angle of the third nanostructures NS3 with respect to the second direction DR2.

In one or more embodiments, the first period, the third period, and the fifth period may be different from each other. In addition, the second period, the fourth period, and the sixth period may be different from each other.

In one or more embodiments, as illustrated in FIG. 5, each of the first nanostructures NS1 may have a rectangular parallelepiped shape. In an embodiment, for example, each of the first nanostructures NS1 may have a rectangular parallelepiped shape on the etch stopper ES. FIG. 5 shows an embodiment of the first nanostructures NS1, but this disclosure is not limited thereto, and the second nanostructures NS2 and the third nanostructures NS3 may also have substantially a same shape as the first nanostructures NS1 of FIG. 5. In an embodiment, for example, each of the second nanostructures NS2 may have a rectangular parallelepiped shape, and each of the third nanostructures NS3 may have a rectangular parallelepiped shape.

Referring further to FIG. 6, each of the first nanostructures NS1 may have a first length LA1 in a horizontal direction thereof. In addition, each of the first nanostructures NS1 may have a second length LA2 in a vertical direction thereof. Here, the vertical direction may be a direction of a longitudinal axis of the first nanostructure NS1. In addition, each of the first nanostructures NS1 may have a height LA3. In an embodiment, for example, the first nanostructures NS1 may have a rectangular parallelepiped shape having the first length LA1 in the horizontal direction, the second length LA2 in the vertical direction, and the height LA3. The height LA3 of the first nanostructures NS1 may be a height or length in the third direction DR3.

In one or more embodiments, the first length LA1 may be different depending on positions of the first nanostructures NS1 in a plan view. In an embodiment, for example, the first lengths LA1 of the adjacent first nanostructures of the first nanostructures NS1 may be different from each other. In an embodiment, for example, adjacent first nanostructures of the first nanostructures NS1 may have different lengths in the horizontal direction thereof. In an embodiment, for example, the first length LA1 of the first nanostructures NS1 may change along the first direction DR1. In an embodiment, for example, the first lengths LA1 of two adjacent first nanostructures adjacent in the first direction DR1 of the first nanostructures NS1 may be different from each other. In an embodiment, for example, the first nanostructure array NSA1 may include first nanostructures NS1 of which the first length LA1 changes at a constant period along the first direction DR1. In one or more embodiments, the first length LA1 of the first nanostructures NS1 may also change along the second direction DR2. In an embodiment, for example, the first lengths LA1 of two adjacent first nanostructures adjacent in the second direction DR2 of the first nanostructures NS1 may be different from each other. In an embodiment, for example, the first nanostructure array NSA1 may include the first nanostructures NS1 in which the first length LA1 changes at a constant period along the first direction DR1 and the second direction DR2. In one or more embodiments, the first length LA1 may change at a seventh period along the first direction DR1, the first length LA1 may change at an eighth period along the second direction DR2, and the seventh period and the eighth period may be different from each other. However, this disclosure is not limited thereto, and the seventh period and the eighth period may be substantially the same as each other. In one or more embodiments, the first length LA1 may gradually change along the first direction DR1 and the second direction DR2.

In one or more embodiments, the second length LA2 may be different depending on positions of the first nanostructures NS1 in a plan view. In an embodiment, for example, the second lengths LA2 of the adjacent first nanostructures of the first nanostructures NS1 may be different from each other. In an embodiment, for example, adjacent first nanostructures of the first nanostructures NS1 may have different lengths in the vertical direction. In an embodiment, for example, the second length LA2 of the first nanostructures NS1 may change along the first direction DR1. In an embodiment, for example, the second length LA2 of two adjacent first nanostructures adjacent in the first direction DR1 of the first nanostructures NS1 may be different from each other. In an embodiment, for example, the first nanostructure array NSA1 may include first nanostructures NS1 of which the second length LA2 changes at a constant period along the first direction DR1. In one or more embodiments, the second length LA2 of the first nanostructures NS1 may also change along the second direction DR2. In an embodiment, for example, the second length LA2 of two adjacent first nanostructures adjacent in the second direction DR2 of the first nanostructures NS1 may be different from each other. In an embodiment, for example, the first nanostructure array NSA1 may include the first nanostructures NS1 in which the second length LA2 changes at a constant period along the first direction DR1 and the second direction DR2. In one or more embodiments, the second length LA2 may change at a ninth period along the first direction DR1, the second length LA2 may change at a tenth period along the second direction DR2, and the ninth period and the tenth period may be different from each other. However, this disclosure is not limited thereto, and the ninth period and the tenth period may be substantially the same as each other. In one or more embodiments, the second length LA2 may gradually change along the first direction DR1 and the second direction DR2.

In one or more embodiments, the height LA3 may be different depending on positions of the first nanostructures NS1 in a plan view. In an embodiment, for example, the height LA3 of the adjacent first nanostructures of the first nanostructures NS1 may be different from each other. In an embodiment, for example, adjacent first nanostructures of the first nanostructures NS1 may have different heights. In an embodiment, for example, the height LA3 of the first nanostructures NS1 may change along the first direction DR1. For example, the height LA3 of two adjacent first nanostructures adjacent in the first direction DR1 of the first nanostructures NS1 may be different from each other. In an embodiment, for example, the first nanostructure array NSA1 may include first nanostructures NS1 of which the height LA3 changes at a constant period along the first direction DR1. In one or more embodiments, the height LA3 of the first nanostructures NS1 may also change along the second direction DR2. In an embodiment, for example, the height LA3 of two adjacent first nanostructures adjacent in the second direction DR2 of the first nanostructures NS1 may be different from each other. In an embodiment, for example, the first nanostructure array NSA1 may include the first nanostructures NS1 in which the height LA3 changes at a constant period along the first direction DR1 and the second direction DR2. In one or more embodiments, the height LA3 may change at a eleventh period along the first direction DR1, the height LA3 may change at a twelfth period along the second direction DR2, and the eleventh period and the twelfth period may be different from each other. However, this disclosure is not limited thereto, and the eleventh period and the twelfth period may be substantially the same as each other. In one or more embodiments, the height LA3 may gradually change along the first direction DR1 and the second direction DR2.

In an embodiment, for example, volumes of the first nanostructures NS1 may be different depending on positions of the first nanostructures NS1 in a plan view. In an embodiment, for example, volumes of adjacent first nanostructures of the first nanostructures NS1 may be different from each other. In an embodiment, for example, the volumes of the first nanostructures NS1 may change along the first direction DR1. In an embodiment, for example, volumes of two adjacent first nanostructures adjacent in the first direction DR1 of the first nanostructures NS1 may be different from each other. In an embodiment, for example, the first nanostructure array NSA1 may include first nanostructures NS1, of which volume changes at a constant period along the first direction DR1. In addition, the volumes of the first nanostructures NS1 may change along the second direction DR2. In an embodiment, for example, the volumes of the first nanostructures NS1 adjacent in the second direction DR2 of the first nanostructures NS1 may be different from each other. In an embodiment, for example, the first nanostructures array NSA1 may include first nanostructures NS1 of which the volume changes at a constant period along the first direction DR1 and the second direction DR2.

Each of the second nanostructures NS2 may have a first length LB1 in a horizontal direction thereof. In addition, each of the second nanostructures NS2 may have a second length LB2 in a vertical direction thereof. In addition, each of the second nanostructures NS2 may have a height LB3. In an embodiment, for example, the second nanostructures NS2 may have a rectangular parallelepiped shape having the first length LB1 in the horizontal direction thereof, the second length LB2 in the vertical direction, and the height LB3. The height LB3 of the second nanostructures NS2 may be a height in the third direction DR3.

In one or more embodiments, the first length LB1 may be different depending on positions of the second nanostructures NS2 in a plan view. In an embodiment, for example, the first lengths LB1 of the adjacent second nanostructures of the second nanostructures NS2 may be different from each other. In an embodiment, for example, adjacent second nanostructures of the second nanostructures NS2 may have different lengths in the horizontal direction. In an embodiment, for example, the first length LB1 of the second nanostructures NS2 may change along the first direction DR1. In an embodiment, for example, the first lengths LB1 of two adjacent second nanostructures adjacent in the first direction DR1 of the second nanostructures NS2 may be different from each other. In an embodiment, for example, the second nanostructure array NSA2 may include second nanostructures NS2 of which the first length LB1 changes at a constant period along the first direction DR1. In one or more embodiments, the first length LB1 of the second nanostructures NS2 may also change along the second direction DR2. In an embodiment, for example, the first lengths LB1 of two adjacent second nanostructures adjacent in the second direction DR2 of the second nanostructures NS2 may be different from each other. In an embodiment, for example, the second nanostructure array NSA2 may include the second nanostructures NS2 in which the first length LB1 changes at a constant period along the first direction DR1 and the second direction DR2. In one or more embodiments, the first length LB1 may change at a thirteenth period along the first direction DR1, the first length LB1 may change at a fourteenth period along the second direction DR2, and the thirteenth period and the fourteenth period may be different from each other. However, this disclosure is not limited thereto, and the thirteenth period and the fourteenth period may be substantially the same as each other. In one or more embodiments, the first length LB1 may gradually change along the first direction DR1 and the second direction DR2.

In one or more embodiments, the second length LB2 may be different depending on positions of the second nanostructures NS2 in a plan view. In an embodiment, for example, the second lengths LB2 of the adjacent second nanostructures of the second nanostructures NS2 may be different from each other. In an embodiment, for example, adjacent second nanostructures of the second nanostructures NS2 may have different lengths in the vertical direction. In an embodiment, for example, the second length LB2 of the second nanostructures NS2 may change along the first direction DR1. In an embodiment, for example, the second length LB2 of two adjacent second nanostructures adjacent in the first direction DR1 of the second nanostructures NS2 may be different from each other. In an embodiment, for example, the second nanostructure array NSA2 may include second nanostructures NS2 of which the second length LB2 changes at a constant period along the first direction DR1. In one or more embodiments, the second length LB2 of the second nanostructures NS2 may also change along the second direction DR2. In an embodiment, for example, the second length LB2 of two adjacent second nanostructures adjacent in the second direction DR2 of the second nanostructures NS2 may be different from each other. In an embodiment, for example, the second nanostructure array NSA2 may include the second nanostructures NS2 in which the second length LB2 changes at a constant period along the first direction DR1 and the second direction DR2. In one or more embodiments, the second length LB2 may change at a fifteenth period along the first direction DR1, the second length LB2 may change at a sixteenth period along the second direction DR2, and the fifteenth period and the sixteenth period may be different from each other. However, this disclosure is not limited thereto, and the fifteenth period and the sixteenth period may be substantially the same as each other. In one or more embodiments, the second length LB2 may gradually change along the first direction DR1 and the second direction DR2.

In one or more embodiments, the height LB3 may be different depending on positions of the second nanostructures NS2 in a plan view. In an embodiment, for example, the height LB3 of the adjacent second nanostructures of the second nanostructures NS2 may be different from each other. In an embodiment, for example, adjacent second nanostructures of the second nanostructures NS2 may have different heights. In an embodiment, for example, the height LB3 of the second nanostructures NS2 may change along the first direction DR1. In an embodiment, for example, the height LB3 of two adjacent second nanostructures adjacent in the first direction DR1 of the second nanostructures NS2 may be different from each other. In an embodiment, for example, the second nanostructure array NSA2 may include second nanostructures NS2 of which the height LB3 changes at a constant period along the first direction DR1. In one or more embodiments, the height LB3 of the second nanostructures NS2 may also change along the second direction DR2. In an embodiment, for example, the height LB3 of two adjacent second nanostructures adjacent in the second direction DR2 of the second nanostructures NS2 may be different from each other. In an embodiment, for example, the second nanostructure array NSA2 may include the second nanostructures NS2 in which the height LB3 changes at a constant period along the first direction DR1 and the second direction DR2. In one or more embodiments, the height LB3 may change at a seventeenth period along the first direction DR1, the height LB3 may change at a eighteenth period along the second direction DR2, and the seventeenth period and the eighteenth period may be different from each other. However, this disclosure is not limited thereto, and the seventeenth period and the eighteenth period may be substantially the same as each other. In one or more embodiments, the height LB3 may gradually change along the first direction DR1 and the second direction DR2.

In an embodiment, for example, volumes of the second nanostructures NS2 may be different depending on positions of the second nanostructures NS2 in a plan view. In an embodiment, for example, volumes of adjacent second nanostructures of the second nanostructures NS2 may be different from each other. In an embodiment, for example, the volumes of the second nanostructures NS2 may change along the first direction DR1. In an embodiment, for example, volumes of two adjacent second nanostructures adjacent in the first direction DR1 of the second nanostructures NS2 may be different from each other. In an embodiment, for example, the second nanostructure array NSA2 may include second nanostructures NS2 of which volume changes at a constant period along the first direction DR1. In addition, the volumes of the second nanostructures NS2 may change along the second direction DR2. In an embodiment, for example, the volumes of the second nanostructures NS2 adjacent in the second direction DR2 among the second nanostructures NS2 may be different from each other. In an embodiment, for example, the second nanostructures array NSA1 may include second nanostructures NS2 of which the volume changes at a constant period along the first direction DR1 and the second direction DR2.

Each of the third nanostructures NS3 may have a first length LC1 in a horizontal direction thereof. In addition, each of the third nanostructures NS3 may have a second length LC2 in a vertical direction thereof. In addition, each of the third nanostructures NS3 may have a height LC3. In an embodiment, for example, each of the third nanostructures NS3 may have a rectangular parallelepiped shape having the first length LC1 in the horizontal direction, the second length LC2 in the vertical direction, and the height LC3. The height LC3 of the third nanostructures NS3 may be a height in the third direction DR3.

In one or more embodiments, the first length LC1 may be different depending on positions of the third nanostructures NS3 in a plan view. In an embodiment, for example, the first lengths LC1 of the adjacent third nanostructures of the third nanostructures NS3 may be different from each other. In an embodiment, for example, adjacent third nanostructures of the third nanostructures NS3 may have different lengths in the horizontal direction. In an embodiment, for example, the first length LC1 of the third nanostructures NS3 may change along the first direction DR1. In an embodiment, for example, the first lengths LC1 of two adjacent third nanostructures adjacent in the first direction DR1 of the third nanostructures NS3 may be different from each other. In an embodiment, for example, the third nanostructure array NSA3 may include third nanostructures NS3 of which the first length LC1 changes at a constant period along the first direction DR1. In one or more embodiments, the first length LC1 of the third nanostructures NS3 may also change along the second direction DR2. In an embodiment, for example, the first lengths LC1 of two adjacent third nanostructures adjacent in the second direction DR2 of the third nanostructures NS3 may be different from each other. In an embodiment, for example, the third nanostructure array NSA3 may include the third nanostructures NS3 in which the first length LC1 changes at a constant period along the first direction DR1 and the second direction DR2. In one or more embodiments, the first length LC1 may change at a nineteenth period along the first direction DR1, the first length LC1 may change at a twentieth period along the second direction DR2, and the nineteenth period and the twentieth period may be different from each other. However, this disclosure is not limited thereto, and the nineteenth period and the twentieth period may be substantially the same as each other. In one or more embodiments, the first length LC1 may gradually change along the first direction DR1 and the second direction DR2.

In one or more embodiments, the second length LC2 may be different depending on positions of the third nanostructures NS3 in a plan view. In an embodiment, for example, the second lengths LC2 of the adjacent third nanostructures of the third nanostructures NS3 may be different from each other. In an embodiment, for example, adjacent third nanostructures of the third nanostructures NS3 may have different lengths in the vertical direction. In an embodiment, for example, the second length LC2 of the third nanostructures NS3 may change along the first direction DR1. In an embodiment, for example, the second length LC2 of two adjacent third nanostructures adjacent in the first direction DR1 of the third nanostructures NS3 may be different from each other. In an embodiment, for example, the third nanostructure array NSA3 may include third nanostructures NS3 of which the second length LC2 changes at a constant period along the first direction DR1. In one or more embodiments, the second length LC2 of the third nanostructures NS3 may also change along the second direction DR2. In an embodiment, for example, the second length LC2 of two adjacent third nanostructures adjacent in the second direction DR2 of the third nanostructures NS3 may be different from each other. In an embodiment, for example, the third nanostructure array NSA3 may include the third nanostructures NS3 in which the second length LC2 changes at a constant period along the first direction DR1 and the second direction DR2. In one or more embodiments, the second length LC2 may change at twenty-first period along the first direction DR1, the second length LC2 may change at a twenty-second period along the second direction DR2, and the twenty-first period and the twenty-second period may be different from each other. However, this disclosure is not limited thereto, and the twenty-first period and the twenty-second period may be substantially the same as each other. I n one or more embodiments, the second length LC2 may gradually change along the first direction DR1 and the second direction DR2.

In one or more embodiments, the height LC3 may be different depending on positions of the third nanostructures NS3 in a plan view. In an embodiment, for example, the height LC3 of the adjacent third nanostructures of the third nanostructures NS3 may be different from each other. In an embodiment, for example, adjacent third nanostructures of the third nanostructures NS3 may have different heights. In an embodiment, for example, the height LC3 of the third nanostructures NS3 may change along the first direction DR1. In an embodiment, for example, the height LC3 of two adjacent third nanostructures adjacent in the first direction DR1 of the third nanostructures NS3 may be different from each other. In an embodiment, for example, the third nanostructure array NSA3 may include third nanostructures NS3 of which the height LC3 changes at a constant period along the first direction DR1. In one or more embodiments, the height LC3 of the third nanostructures NS3 may also change along the second direction DR2. In an embodiment, for example, the height LC3 of two adjacent third nanostructures adjacent in the second direction DR2 of the third nanostructures NS3 may be different from each other. In an embodiment, for example, the third nanostructure array NSA3 may include the third nanostructures NS3 in which the height LC3 changes at a constant period along the first direction DR1 and the second direction DR2. In one or more embodiments, the height LC3 may change at a twenty-third period along the first direction DR1, the height LC3 may change at a twenty-fourth period along the second direction DR2, and the twenty-third period and the twenty-fourth period may be different from each other. However, this disclosure is not limited thereto, and the twenty-third period and the twenty-fourth period may be substantially the same as each other. In one or more embodiments, the height LC3 may gradually change along the first direction DR1 and the second direction DR2.

In an embodiment, for example, volumes of the third nanostructures NS3 may be different depending on positions of the third nanostructures NS3 in a plan view. In an embodiment, for example, volumes of adjacent third nanostructures of the third nanostructures NS3 may be different from each other. In an embodiment, for example, the volumes of the third nanostructures NS3 may change along the first direction DR1. In an embodiment, for example, volumes of two adjacent third nanostructures adjacent in the first direction DR1 of the third nanostructures NS3 may be different from each other. In an embodiment, for example, the third nanostructure array NSA3 may include third nanostructures NS3 of which volume changes at a constant period along the first direction DR1. In addition, the volumes of the third nanostructures NS3 may change along the second direction DR2. In an embodiment, for example, the volumes of the third nanostructures NS3 adjacent in the second direction DR2 of the third nanostructures NS3 may be different from each other. In an embodiment, for example, the third nanostructures array NSA1 may include third nanostructures NS3 of which the volume changes at a constant period along the first direction DR1 and the second direction DR2.

In one or more embodiments, as illustrated in FIG. 4, a separation distance LD1 between adjacent first nanostructures of the first nanostructures NS1, a separation distance LD2 between adjacent second nanostructures of the second nanostructures NS2, and a separation distance LD3 between adjacent third nanostructures of the third nanostructures NS3 may be different from each other. In an embodiment, for example, the separation distance LD1 between adjacent first nanostructures in the first direction DR1 of the first nanostructures NS1 may be greater than the separation distance LD2 between adjacent second nanostructures in the first direction DR1 of the second nanostructures NS2. In addition, the separation distance LD2 between adjacent second nanostructures in the first direction DR1 of the second nanostructures NS2 in the first direction DR1 may be greater than the separation distance LD3 between adjacent third nanostructures in the first direction DR1 of the third nanostructures NS3.

A magnitude relationship between the separation distance LD1, the separation distance LD2, and the separation distance LD3 may vary according to wavelength of light emitted from each of the first pixel area, the second pixel area, and the third pixel area. In an embodiment, as described above, the first pixel area may emit red light, the second pixel area may emit green light, and the third pixel area may emit blue light. In such an embodiment, the separation distance LD1 between adjacent first nanostructures of the first nanostructures NS1 disposed in the first pixel area emitting the red light that have longest wavelength may be greater than the separation distance LD2 between adjacent second nanostructures of the second nanostructures NS2 and the separation distance LD3 between adjacent third nanostructures of the third nanostructures NS3. In addition, the separation distance LD3 between adjacent third nanostructures of the third nanostructures NS3 disposed in the third pixel area emitting the blue light that have shortest wavelength may be less than the separation distance LD1 between adjacent first nanostructures of the first nanostructures NS1 and the separation distance LD2 between adjacent second nanostructures of the second nanostructures NS2.

In such an embodiment, the separation distance LD1 may mean a separation distance in the first direction DR1 between straight lines extending in the second direction DR2 and passing through centers of upper side surfaces of adjacent first nanostructures, respectively, in a plan view. The separation distance LD1 may be substantially constant over the first pixel area. The separation distance LD2 may mean a separation distance in the first direction DR1 between straight lines extending in the second direction DR2 and passing through centers of upper side surfaces of adjacent second nanostructures, respectively, in a plan view. The separation distance LD2 may be substantially constant over the second pixel area. The separation distance LD3 may mean a separation distance in the first direction DR1 between straight lines extending in the second direction DR2 and passing through centers of upper side surfaces of adjacent third nanostructures, respectively, in a plan view. The separation distance LD3 may be substantially constant over the second pixel area.

In one or more embodiments, each of the first nanostructures NS1, the second nanostructures NS2, and the third nanostructures NS3 may be formed by a dry etching process. In an embodiment, for example, a first preliminary layer may be formed on the etch stopper ES, and a portion of the first preliminary layer may be removed by a dry etching process to form the first nanostructures NS1. In addition, a second preliminary layer may be formed on the etch stopper ES, and a portion of the second preliminary layer may be removed by a dry etching process to form the second nanostructures NS2. In addition, a third preliminary layer may be formed on the etch stopper ES, and a portion of the third preliminary layer may be removed by a dry etching process to form the third nanostructures NS3. However, this disclosure is not limited thereto, and each of the first nanostructures NS1, the second nanostructures NS2, and the third nanostructures NS3 may be formed through various processes. In an embodiment, for example, each of the first nanostructures NS1, the second nanostructures NS2, and the third nanostructures NS3 may be formed through a nano imprint process.

In one or more embodiments, each of the first nanostructures NS1, the second nanostructures NS2, and the third nanostructures NS3 may include a dielectric having a high refractive index. In an embodiment, for example, each of the first nanostructures NS1, the second nanostructures NS2, and the third nanostructures NS3 may include amorphous silicon, polysilicon, titanium dioxide (“TiO₂”), zinc oxide (“ZnO”), aluminum oxide (“Al₂O₃”), silicon dioxide (“SiO₂”), hollow silica, polyimide, and/or the like. These materials may be used alone or in combination with each other. However, this disclosure is not limited thereto, and each of the first nanostructures NS1, the second nanostructures NS2, and the third nanostructures NS3 may include various materials having a high refractive index.

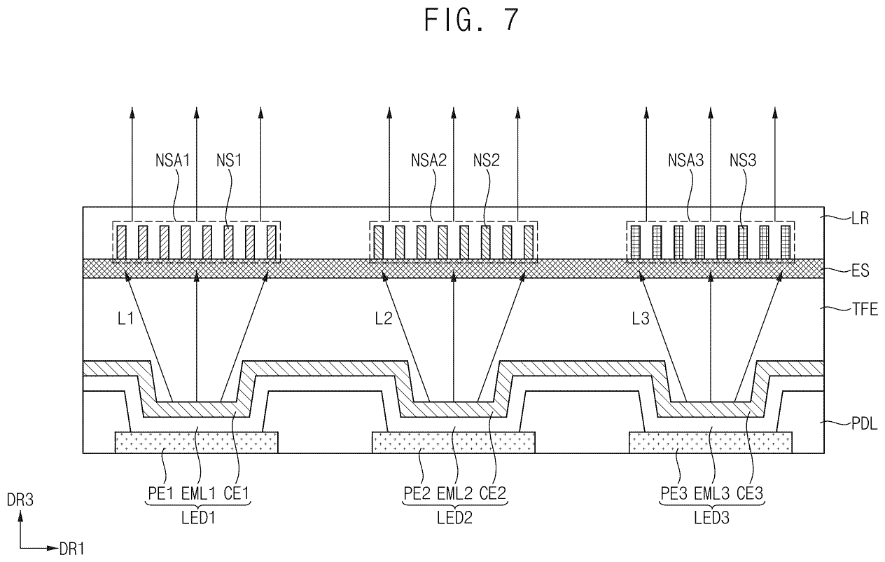

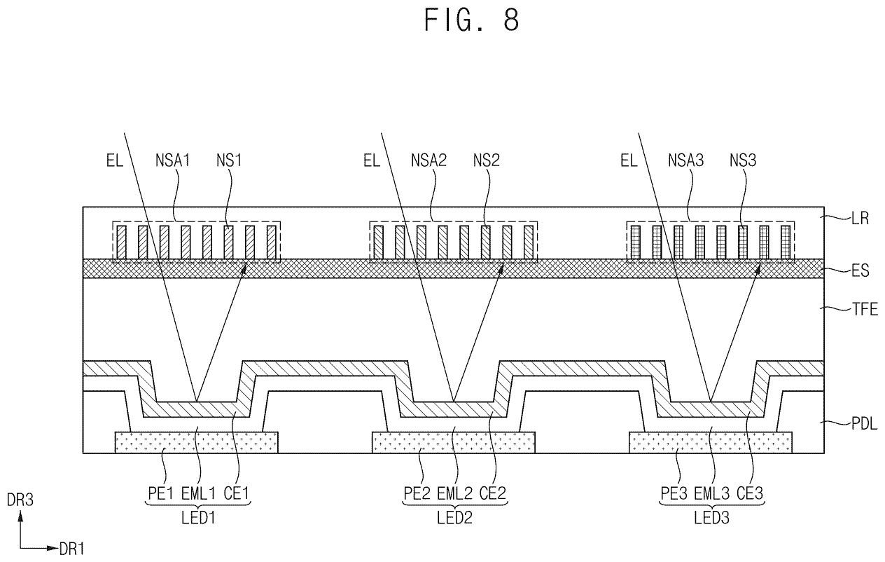

FIG. 7 is a cross-sectional view illustrating a path of light emitted from a light-emitting element of the display device of FIG. 3. FIG. 8 is a cross-sectional view illustrating a path of external light incident on the display device of FIG. 3.

Referring to FIGS. 4, 5, 6, and 7, in an embodiment, as described above, the first length LA1 of the first nanostructures NS1 may gradually change along the first direction DR1 and the second directions DR2. In addition, the second length LA2 of the first nanostructures NS1 may gradually change along the first direction DR1 and the second direction DR2. In addition, the heights LA3 of the first nanostructures NS1 may gradually change along the first direction DR1 and the second direction DR2. In an embodiment, for example, the volumes of the first nanostructures NS1 may gradually change along the first direction DR1 and the second direction DR2. Accordingly, first light L1 emitted from the first light-emitting element LED1 may be condensed. In an embodiment, for example, the first light-emitting element LED1 may emit the first light L1 in all directions, and the first light L1 may travel in the third direction DR3 (or a direction substantially parallel to the third direction DR3) by the first nanostructures NS1. Accordingly, efficiency and intensity of the first light L1 emitted from the first light-emitting element LED1 may increase.

In such an embodiment, as described above, the first length LB1 of the second nanostructures NS2 may gradually change along the first direction DR1 and the second direction DR2. In addition, the second length LB2 of the second nanostructures NS2 may gradually change along the first direction DR1 and the second direction DR2. In addition, the height LB3 of the second nanostructures NS2 may gradually change along the first direction DR1 and the second direction DR2. In an embodiment, for example, the volumes of the second nanostructures NS2 may gradually change along the first direction DR1 and the second direction DR2. Accordingly, second light L2 emitted from the second light-emitting element LED2 may be condensed. In an embodiment, for example, the second light-emitting element LED2 may emit the second light L2 in all directions, and the second light L2 may travel in the third direction DR3 (or a direction substantially parallel to the third direction DR3). Accordingly, efficiency and intensity of the second light L2 emitted from the second light-emitting element LED2 may increase.

In such an embodiment, as described above, the first length LC1 of the third nanostructures NS3 may gradually change along the first direction DR1 and the second direction DR2. In addition, the second lengths LC2 of the third nanostructures NS3 may gradually change along the first direction DR1 and the second direction DR2. In addition, the heights LC3 of the third nanostructures NS3 may gradually change along the first direction DR1 and the second direction DR2. In an embodiment, for example, the volumes of the third nanostructures NS3 may gradually change along the first direction DR1 and the second direction DR2. Accordingly, third light L3 emitted from the third light-emitting element LED3 may be condensed. In an embodiment, for example, the third light-emitting element LED3 may emit the third light L3 in all directions, and the third light L3 may travel in the third direction DR3 (or a direction substantially parallel to the third direction DR3). Accordingly, efficiency and intensity of the third light L3 emitted from the third light-emitting element LED3 may increase.

In an embodiment, for example, as the display device (e.g., the display device DD of FIG. 3) includes the metasurface layer (e.g., the metasurface layer MSL of FIG. 2), efficiency and intensity of each of the first light L1, the second light L2, and the third light L3 may increase even if no microlens layer is provided on each of the first light-emitting element LED1, the second light-emitting element LED2, and the third light-emitting element LED3. Therefore, in such an embodiment, the microlens and/or the like may be omitted, thereby reducing a manufacturing cost of the display device.

Referring to FIGS. 4, 5, 6, and 8, in an embodiment, external light EL incident on the display device may be reflected by an electrode included in the display device and/or the like. In an embodiment, for example, the external light EL incident on the display device may be reflected by the first common electrode CE1, the second common electrode CE2, and the third common electrode CE3. In such an embodiment, as described above, the first nanostructure array NSA1 may include first nanostructures NS1 in which the inclination angle θ1 with respect to the first direction DR1 changes at a constant period along the first direction DR1 and the second direction DR2. In addition, the second nanostructure array NSA2 may include second nanostructures NS2 in which the inclination angle θ2 with respect to the first direction DR1 changes at a constant period along the first direction DR1 and the second direction DR2. In addition, the third nanostructure array NSA3 may include third nanostructures NS3 in which the inclination angle θ3 with respect to the first direction DR1 changes at a constant period along the first direction DR1 and the second direction DR2. Accordingly, in such an embodiment, reflection of the external light EL incident on the display device may be blocked. In an embodiment, for example, the external light EL reflected by the first common electrode CE1, the second common electrode CE2, and the third common electrode CE3 may be blocked by the first nanostructure array NSA1, the second nanostructure array NSA2, and the third nanostructure array NSA3. In an embodiment, for example, as the display device includes the metasurface layer, reflection of the external light EL incident on the display device may be blocked even when no separate polarizing plate and/or the like is provided on the first light-emitting element LED1, the second light-emitting element LED2, and the third light-emitting element LED3. Therefore, in such an embodiment, the polarizing plate and/or the like may be omitted, thereby reducing the manufacturing cost of the display device.

In embodiments of the disclosure, as described above, the display device includes the metasurface layer, reflection of the external light EL incident on the display device may be blocked, and at the same time, the first light L1 emitted from the first light-emitting element LED1, the second light L2 emitted from the second light-emitting element LED2, and the third light L3 emitted from the third light-emitting element LED3 may be condensed. Accordingly, the polarizing plate, the microlens, and/or the like may be omitted, and thus the manufacturing costs of the display device may be reduced. In addition, as the polarizing plate, the microlens, and/or the like may be omitted, a thickness of the display device may be reduced. Accordingly, the display device having a structure suitable for a display device including a foldable area such as a foldable display device and/or the like may be provided.

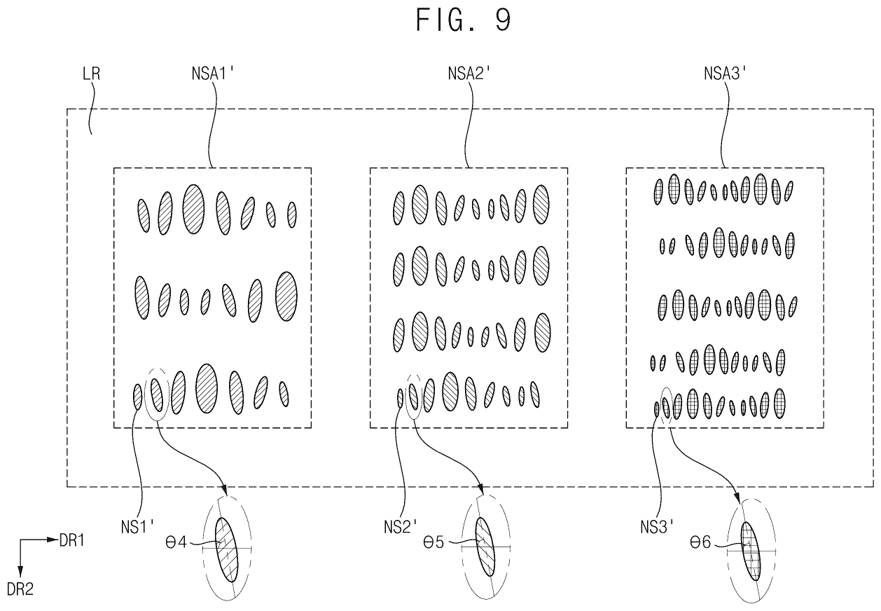

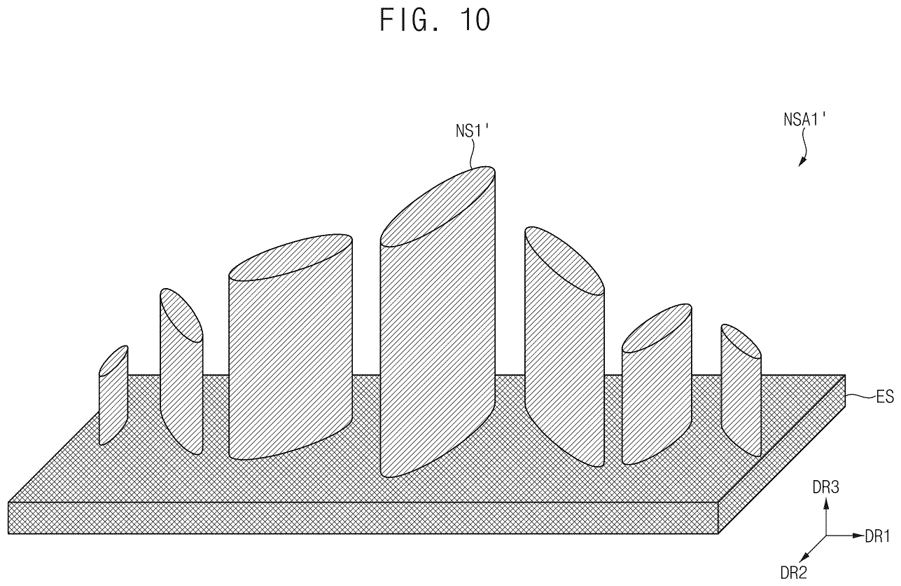

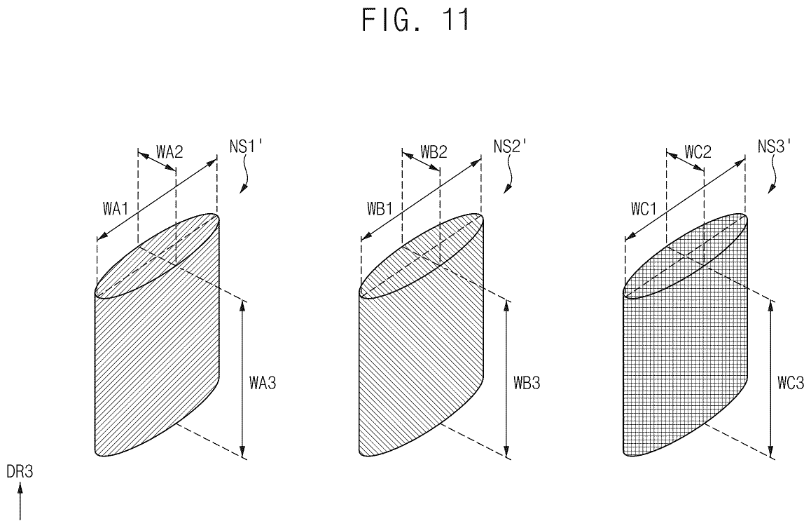

FIG. 9 is a schematic plan view illustrating an example of a partial area of the display device of FIG. 1. FIG. 10 is a perspective view illustrating a first nanostructure array included in the display device of FIG. 9. FIG. 11 is a perspective view illustrating a first nanostructure, a second nanostructure, and a third nanostructure included in the display device of FIG. 9.

In detail, FIG. 9 is a plan view illustrating a first nanostructure array NSA1′, a second nanostructure array NSA2′, a third nanostructure array NSA3′, and the low refractive index layer LR. In addition, FIG. 11 is an enlarged perspective view of each of a first nanostructure NS1′, a second nanostructure NS2′, and a third nanostructure NS3′.

Hereinafter, features of the first nanostructure array NSA1, the second nanostructure array NSA2, and the third nanostructure array NSA3 shown in FIGS. 9 to 11 that are different from those described above with reference to FIGS. 4, 5, and 6 will be mainly described.

Referring to FIGS. 9, 10, and 11, in an embodiment, the metasurface layer (e.g., the meta-surface layer MSL of FIG. 2) may include a first nanostructure array NSA1′, a second nanostructure array NSA2′, and a third nanostructure array NSA3′.

The first nanostructure array NS1′ may include first nanostructures NS1′. The first nanostructures NS1′ may be repeatedly arranged along the first direction DR1 and the second direction DR2. In an embodiment, for example, the first nanostructures NS1′ may be repeatedly arranged in the first direction DR1 and the second direction DR2 in the first pixel area (e.g., the first pixel area PX1 of FIG. 3). The first nanostructures NS1′ may be spaced apart from each other in a plan view.

The second nanostructure array NS2′ may include second nanostructures NS2′. The second nanostructures NS2′ may be repeatedly arranged in the first direction DR1 and the second direction DR2. In an embodiment, for example, the second nanostructures NS2′ may be repeatedly arranged in the first direction DR1 and the second direction DR2 in the second pixel area (e.g., the second pixel area PX2 of FIG. 3). The second nanostructures NS2′ may be spaced apart from each other in a plan view.

The third nanostructure array NSA3′ may include third nanostructures NS3′. The third nanostructures NS3′ may be repeatedly arranged in the first direction DR1 and the second direction DR2. In an embodiment, for example, the third nanostructures NS3′ may be repeatedly arranged in the first direction DR1 and the second direction DR2 in the third pixel area (e.g., the third pixel area PX3 of FIG. 3). The third nanostructures NS3′ may be spaced apart from each other in a plan view.

In one or more embodiments, as illustrated in FIG. 10, each of the first nanostructures NS1′ may have a shape of an elliptical (or oval) pillar. In an embodiment, for example, the first nanostructures NS1′ may have the shape of the elliptical pillar on the etch stopper ES. Although FIG. 10 may show the first nanostructures NS1′, this disclosure is not limited thereto, and the second nanostructures NS2′ and the third nanostructures NS3′ may also have substantially a same shape as the first nanostructures NS1′ of FIG. 10. In an embodiment, for example, each of the second nanostructures NS2′ may have a shape of an elliptical pillar, and each of the third nanostructures NS3′ may have a shape of an elliptical pillar. In an embodiment, for example, each of the first nanostructures NS1′ may have an elliptical shape including a major axis and a minor axis in a plan view. In addition, each of the second nanostructures NS2′ may have an elliptical shape including a major axis and a minor axis in a plan view. In addition, each of the third nanostructures NS3′ may have an elliptical shape including a major axis and a minor axis in a plan view.

In an embodiment, as illustrated in FIG. 11, the major axis of the first nanostructures NS1′ may have a first length WA1. In addition, the minor axis of the first nanostructures NS1′ may have a second length WA2. In addition, the first nanostructures NS1′ may have a height WA3. In an embodiment, for example, the first nanostructures NS1′ may have a shape of an elliptical pillar having the major axis having the first length WA1, the minor axis having the second length WA2, and a height WA3. The height WA3 may be a height of a center of the elliptical shape in the third direction DR3.

In one or more embodiments, the first length WA1 may be different depending on positions of the first nanostructures NS1′. In an embodiment, for example, first lengths WA1 of adjacent first nanostructures of the first nanostructures NS1′ may be different from each other. In an embodiment, for example, lengths of major axes of adjacent first nanostructures of the first nanostructures NS1′ may be different from each other. In an embodiment, for example, the first length WA1 of the first nanostructures NS1′ may change along the first direction DR1. In an embodiment, for example, the first lengths WA1 of two adjacent first nanostructures adjacent in the first direction DR1 of the first nanostructures NS1′ may be different from each other. In an embodiment, for example, the first nanostructure array NSA1′ may include first nanostructures NS1′ in which the first length WA1 changes at a constant period along the first direction DR1. In one or more embodiments, the first length WA1 of the first nanostructures NS1′ may also change along the second direction DR2. In an embodiment, for example, the first lengths WA1 of two adjacent first nanostructures NS1′ adjacent in the second direction DR2 may be different from each other. In an embodiment, for example, the first nanostructure array NSA1′ may include first nanostructures NS1′ in which the first length WA1 changes at a constant period along the first direction DR1 and the second direction DR2. In one or more embodiments, the first length WA1 may gradually change along the first direction DR1 and the second direction DR2.

In one or more embodiments, the second length WA2 may be different depending on positions of the first nanostructures NS1′. In an embodiment, for example, second lengths WA2 of adjacent first nanostructures of the first nanostructures NS1′ may be different from each other. In an embodiment, for example, lengths of minor axes of adjacent first nanostructures of the first nanostructures NS1′ may be different from each other. In an embodiment, for example, the second length WA2 of the first nanostructures NS1′ may change along the first direction DR1. In an embodiment, for example, the second lengths WA2 of two adjacent first nanostructures adjacent in the first direction DR1 of the first nanostructures NS1′may be different from each other. In an embodiment, for example, the first nanostructure array NSA1′ may include first nanostructures NS1′ in which the second length WA2 changes at a constant period along the first direction DR1. In one or more embodiments, the second length WA2 of the first nanostructures NS1′ may also change along the second direction DR2. In an embodiment, for example, the second lengths WA2 of two adjacent first nanostructures NS1′adjacent in the second direction DR2 may be different from each other. In an embodiment, for example, the first nanostructure array NSA1′ may include first nanostructures NS1′ in which the second length WA2 changes at a constant period along the first direction DR1 and the second direction DR2. In one or more embodiments, the second length WA2 may gradually change along the first direction DR1 and the second direction DR2.

In one or more embodiments, the height WA3 may be different depending on positions of the first nanostructures NS1′. In an embodiment, for example, heights WA3 of adjacent first nanostructures of the first nanostructures NS1′ may be different from each other. In an embodiment, for example, the height WA3 of the first nanostructures NS1′ may change along the first direction DR1. In an embodiment, for example, the heights WA3 of two adjacent first nanostructures adjacent in the first direction DR1 of the first nanostructures NS1′ may be different from each other. In an embodiment, for example, the first nanostructure array NSA1′may include first nanostructures NS1′ in which the height WA3 changes at a constant period along the first direction DR1. In one or more embodiments, the height WA3 of the first nanostructures NS1′ may also change along the second direction DR2. For example, the heights WA3 of two adjacent first nanostructures NS1′ adjacent in the second direction DR2 may be different from each other. In an embodiment, for example, the first nanostructure array NSA1′ may include first nanostructures NS1′ in which the height WA3 changes at a constant period along the first direction DR1 and the second direction DR2. In one or more embodiments, the height WA3 may gradually change along the first direction DR1 and the second direction DR2.

As each of the first length WA1, the second length WA2, and the height WA3 of the first nanostructures NS1′ gradually changes along the first direction DR1 and the second direction DR2, the first light (e.g., the first light L1 of FIG. 7) emitted from the first light-emitting element (e.g., the first light-emitting element LED1 of FIG. 7) may be condensed. In an embodiment, for example, the first light-emitting element may emit the first light in all directions, and the first light may travel in the third direction DR3 (or a direction substantially parallel to the third direction DR3) by the first nanostructures NS1′. Therefore, efficiency and intensity of the first light emitted from the first light-emitting element may increase.

As illustrated in FIG. 11, the major axis of the second nanostructures NS2′ may have a first length WB1. In addition, the minor axis of the second nanostructures NS2′ may have a second length WB2. In addition, the second nanostructures NS2′ may have a height WB3. In an embodiment, for example, the second nanostructures NS2′ may have a shape of an elliptical pillar having the major axis having the first length WB1, the minor axis having the second length WB2, and the height WB3. The height WB3 may be a height of a center of the elliptical shape in the third direction DR3.

In one or more embodiments, the first length WB1 may be different depending on positions of the second nanostructures NS2′. In an embodiment, for example, first lengths WB1 of adjacent second nanostructures of the second nanostructures NS2′ may be different from each other. In an embodiment, for example, lengths of major axes of adjacent second nanostructures of the second nanostructures NS2′ may be different from each other. In an embodiment, for example, the first length WB1 of the second nanostructures NS2′ may change along the first direction DR1. In an embodiment, for example, the first lengths WB1 of two adjacent second nanostructures adjacent in the first direction DR1 of the second nanostructures NS2′ may be different from each other. In an embodiment, for example, the second nanostructure array NSA2′ may include second nanostructures NS2′ in which the first length WB1 changes at a constant period along the first direction DR1. In one or more embodiments, the first length WB1 of the second nanostructures NS2′ may also change along the second direction DR2. In an embodiment, for example, the first lengths WB1 of two adjacent second nanostructures NS2′ adjacent in the second direction DR2 may be different from each other. In an embodiment, for example, the second nanostructure array NSA2′ may include second nanostructures NS2′ in which the first length WB1 changes at a constant period along the first direction DR1 and the second direction DR2. In one or more embodiments, the first length WB1 may gradually change along the first direction DR1 and the second direction DR2.

In one or more embodiments, the second length WB2 may be different depending on positions of the second nanostructures NS2′. In an embodiment, for example, second lengths WB2 of adjacent second nanostructures of the second nanostructures NS2′ may be different from each other. In an embodiment, for example, lengths of minor axes of adjacent second nanostructures of the second nanostructures NS2′ may be different from each other. In an embodiment, for example, the second length WB2 of the second nanostructures NS2′ may change along the first direction DR1. In an embodiment, for example, the second lengths WB2 of two adjacent second nanostructures adjacent in the first direction DR1 of the second nanostructures NS2′ may be different from each other. In an embodiment, for example, the second nanostructure array NSA2′ may include second nanostructures NS2′ in which the second length WB2 changes at a constant period along the first direction DR1. In one or more embodiments, the second length WB2 of the second nanostructures NS2′ may also change along the second direction DR2. In an embodiment, for example, the second lengths WB2 of two adjacent second nanostructures NS2′ adjacent in the second direction DR2 may be different from each other. In an embodiment, for example, the second nanostructure array NSA2′ may include second nanostructures NS2′ in which the second length WB2 changes at a constant period along the first direction DR1 and the second direction DR2. In one or more embodiments, the second length WB2 may gradually change along the first direction DR1 and the second direction DR2.

In one or more embodiments, the height WB3 may be different depending on positions of the second nanostructures NS2′. In an embodiment, for example, heights WB3 of adjacent second nanostructures of the second nanostructures NS2′ may be different from each other. In an embodiment, for example, the height WB3 of the second nanostructures NS2′ may change along the first direction DR1. In an embodiment, for example, the heights WB3 of two adjacent second nanostructures adjacent in the first direction DR1 of the second nanostructures NS2′ may be different from each other. In an embodiment, for example, the second nanostructure array NSA2′ may include second nanostructures NS2′ in which the height WB3 changes at a constant period along the first direction DR1. In one or more embodiments, the height WB3 of the second nanostructures NS2′ may also change along the second direction DR2. In an embodiment, for example, the heights WB3 of two adjacent second nanostructures NS2′ adjacent in the second direction DR2 may be different from each other. In an embodiment, for example, the second nanostructure array NSA2′ may include second nanostructures NS2′ in which the height WB3 changes at a constant period along the first direction DR1 and the second direction DR2. In one or more embodiments, the height WB3 may gradually change along the first direction DR1 and the second direction DR2.

As each of the first length WB1, the second length WB2, and the height WB3 of the second nanostructures NS2′ gradually changes along the first direction DR1 and the second direction DR2, the second light (e.g., the second light L2 of FIG. 7) emitted from the second light-emitting element (e.g., the second light-emitting element LED2 of FIG. 7) may be condensed. In an embodiment, for example, the second light-emitting element may emit the second light in all directions, and the second light may travel in the third direction DR3 (or a direction substantially parallel to the third direction DR3) by the second nanostructures NS2′. Therefore, efficiency and intensity of the second light emitted from the second light-emitting element may increase.

As illustrated in FIG. 11, the major axis of the third nanostructures NS3′ may have a first length WC1. In addition, the minor axis of the third nanostructures NS3′ may have a second length WC2. In addition, the third nanostructures NS3′ may have a height WC3. In an embodiment, for example, the third nanostructures NS3′ may have a shape of an elliptical pillar having the major axis having the first length WC1, the minor axis having the second length WC2, and the height WC3. The height WC3 may be a height of a center of the elliptical shape in the third direction DR3.

In one or more embodiments, the first length WC1 may be different depending on positions of the third nanostructures NS3′. In an embodiment, for example, first lengths WC1 of adjacent third nanostructures of the third nanostructures NS3′ may be different from each other. In an embodiment, for example, lengths of major axes of adjacent third nanostructures of the third nanostructures NS3′ may be different from each other. In an embodiment, for example, the first length WC1 of the third nanostructures NS3′ may change along the first direction DR1. In an embodiment, for example, the first lengths WC1 of two adjacent third nanostructures adjacent in the first direction DR1 of the third nanostructures NS3′ may be different from each other. In an embodiment, for example, the third nanostructure array NSA3′ may include third nanostructures NS3′ in which the first length WC1 changes at a constant period along the first direction DR1. In one or more embodiments, the first length WC1 of the third nanostructures NS3′ may also change along the second direction DR2. In an embodiment, for example, the first lengths WC1 of two adjacent third nanostructures NS3′ adjacent in the second direction DR2 may be different from each other. In an embodiment, for example, the third nanostructure array NSA3′ may include third nanostructures NS3′ in which the first length WC1 changes at a constant period along the first direction DR1 and the second direction DR2. In one or more embodiments, the first length WC1 may gradually change along the first direction DR1 and the second direction DR2.

In one or more embodiments, the second length WC2 may be different depending on positions of the third nanostructures NS3′. In an embodiment, for example, second lengths WC2 of adjacent third nanostructures of the third nanostructures NS3′ may be different from each other. In an embodiment, for example, lengths of minor axes of adjacent third nanostructures of the third nanostructures NS3′ may be different from each other. In an embodiment, for example, the second length WC2 of the third nanostructures NS3′ may change along the first direction DR1. In an embodiment, for example, the second lengths WC2 of two adjacent third nanostructures adjacent in the first direction DR1 of the third nanostructures NS3′ may be different from each other. In an embodiment, for example, the third nanostructure array NSA3′ may include third nanostructures NS3′ in which the second length WC2 changes at a constant period along the first direction DR1. In one or more embodiments, the second length WC2 of the third nanostructures NS3′ may also change along the second direction DR2. In an embodiment, for example, the second lengths WC2 of two adjacent third nanostructures NS3′ adjacent in the second direction DR2 may be different from each other. In an embodiment, for example, the third nanostructure array NSA3′ may include third nanostructures NS3′ in which the second length WC2 changes at a constant period along the first direction DR1 and the second direction DR2. In one or more embodiments, the second length WC2 may gradually change along the first direction DR1 and the second direction DR2.

In one or more embodiments, the height WC3 may be different depending on positions of the third nanostructures NS3′. In an embodiment, for example, heights WC3 of adjacent third nanostructures of the third nanostructures NS3′ may be different from each other. In an embodiment, for example, the height WC3 of the third nanostructures NS3′ may change along the first direction DR1. In an embodiment, for example, the heights WC3 of two adjacent third nanostructures adjacent in the first direction DR1 of the third nanostructures NS3′ may be different from each other. In an embodiment, for example, the third nanostructure array NSA3′may include third nanostructures NS3′ in which the height WC3 changes at a constant period along the first direction DR1. In one or more embodiments, the height WC3 of the third nanostructures NS3′ may also change along the second direction DR2. In an embodiment, for example, the heights WC3 of two adjacent third nanostructures NS3′ adjacent in the second direction DR2 may be different from each other. In an embodiment, for example, the third nanostructure array NSA3′ may include third nanostructures NS3′ in which the height WC3 changes at a constant period along the first direction DR1 and the second direction DR2. In one or more embodiments, the height WC3 may gradually change along the first direction DR1 and the second direction DR2.

As each of the first length WC1, the second length WC2, and the height WC3 of the third nanostructures NS3′ gradually changes along the first direction DR1 and the second direction DR2, the third light (e.g., the third light L3 of FIG. 7) emitted from the third light-emitting element (e.g., the third light-emitting element LED2 of FIG. 7) may be condensed. In an embodiment, for example, the third light-emitting element may emit the third light in all directions, and the third light may travel in the third direction DR3 (or a direction substantially parallel to the third direction DR3) by the third nanostructures NS3′. Therefore, efficiency and intensity of the third light emitted from the third light-emitting element may increase.

In one or more embodiments, a degree of inclination of the first nanostructures NS1′ in a plan view may change depending on positions of the first nanostructures NS1′ in a plan view. In an embodiment, for example, a degree of inclination of adjacent first nanostructures of the first nanostructures NS1′ in a plan view may be different from each other. In an embodiment, for example, as illustrated in FIG. 9, an inclination angle θ4 of the first nanostructures NS1′ with respect to the first direction DR1 may be different depending on positions of the first nanostructures NS1′ in a plan view. In an embodiment, for example, the inclination angle θ4 of the first nanostructures NS1′ with respect to the first direction DR1 may change along the first direction DR1. In an embodiment, for example, inclination angles with respect to the first direction DR1 of two adjacent first nanostructures adjacent in the first direction DR1 of the first nanostructures NS1′ may be different from each other. In an embodiment, for example, the first nanostructure array NSA1′ may include first nanostructures NS1′ in which the inclination angle θ4 with respect to the first direction DR1 changes at a constant period along the first direction DR1. In one or more embodiments, the inclination angle θ4 of the first nanostructures NS1′ with respect to the first direction DR1 may also change along the second direction DR2. In an embodiment, for example, Inclination angles with respect to the first direction DR1 of two adjacent first nanostructures adjacent in the second direction DR2 of the first nanostructures NS1′ may be different from each other. In an embodiment, for example, the first nanostructure array NSA1′ may include first nanostructures NS1′ in which the inclination angle θ4 with respect to the first direction DR1 changes at a constant period along the first direction DR1 and the second direction DR2. In one or more embodiments, the inclination angle θ4 of the first nanostructures NS1′ with respect to the first direction DR1 may gradually change along the first direction DR1 and the second direction DR2. The inclination angle θ4 may be an angle formed between the first direction DR1 and the major axis of the first nanostructures NS1′.

In one or more embodiments, a degree of inclination of the second nanostructures NS2′ in a plan view may change depending on positions of the second nanostructures NS2′ in a plan view. In an embodiment, for example, a degree of inclination of adjacent second nanostructures of the second nanostructures NS2′ in a plan view may be different from each other. In an embodiment, for example, as illustrated in FIG. 9, an inclination angle θ5 of the second nanostructures NS2′ with respect to the first direction DR1 may be different depending on positions of the second nanostructures NS2′ in a plan view. In an embodiment, for example, the inclination angle θ5 of the second nanostructures NS2′ with respect to the first direction DR1 may change along the first direction DR1. In an embodiment, for example, Inclination angles with respect to the first direction DR1 of two adjacent second nanostructures adjacent in the first direction DR1 of the second nanostructures NS2′ may be different from each other. In an embodiment, for example, the second nanostructure array NSA2′ may include second nanostructures NS2′ in which the inclination angle θ5 with respect to the first direction DR1 changes at a constant period along the first direction DR1. In one or more embodiments, the inclination angle θ5 of the second nanostructures NS2′ with respect to the first direction DR1 may also change along the second direction DR2. In an embodiment, for example, Inclination angles with respect to the first direction DR1 of two adjacent second nanostructures adjacent in the second direction DR2 of the second nanostructures NS2′ may be different from each other. In an embodiment, for example, the second nanostructure array NSA2′ may include second nanostructures NS2′ in which the inclination angle θ5 with respect to the first direction DR1 changes at a constant period along the first direction DR1 and the second direction DR2. In one or more embodiments, the inclination angle θ5 of the second nanostructures NS2′ with respect to the first direction DR1 may gradually change along the first direction DR1 and the second direction DR2. The inclination angle θ5 may be an angle formed between the first direction DR1 and the major axis of the second nanostructures NS2′.

In one or more embodiments, a degree of inclination of the third nanostructures NS3′ in a plan view may change depending on positions of the third nanostructures NS3′ in a plan view. In an embodiment, for example, a degree of inclination of adjacent third nanostructures of the third nanostructures NS3′ in a plan view may be different from each other. In an embodiment, for example, as illustrated in FIG. 9, an inclination angle θ6 of the third nanostructures NS3′ with respect to the first direction DR1 may be different depending on positions of the third nanostructures NS3′ in a plan view. In an embodiment, for example, the inclination angle θ6 of the third nanostructures NS3′ with respect to the first direction DR1 may change along the first direction DR1. In an embodiment, for example, Inclination angles with respect to the first direction DR1 of two adjacent third nanostructures adjacent in the first direction DR1 of the third nanostructures NS3′ may be different from each other. In an embodiment, for example, the third nanostructure array NSA3′ may include third nanostructures NS3′ in which the inclination angle θ6 with respect to the first direction DR1 changes at a constant period along the first direction DR1. In one or more embodiments, the inclination angle θ6 of the third nanostructures NS3′ with respect to the first direction DR1 may also change along the second direction DR2. In an embodiment, for example, Inclination angles with respect to the first direction DR1 of two adjacent third nanostructures adjacent in the second direction DR2 of the third nanostructures NS3′ may be different from each other. In an embodiment, for example, the third nanostructure array NSA3′ may include third nanostructures NS3′ in which the inclination angle θ6 with respect to the first direction DR1 changes at a constant period along the first direction DR1 and the second direction DR2. In one or more embodiments, the inclination angle θ6 of the third nanostructures NS3′ with respect to the first direction DR1 may gradually change along the first direction DR1 and the second direction DR2. The inclination angle θ6 may be an angle formed between the first direction DR1 and the major axis of the third nanostructures NS3′.

As the first nanostructure array NSA1′ includes first nanostructures NS1′ in which the inclination angle θ4 with respect to the first direction DR1 changes at a constant period along the first direction DR1 and the second direction DR2, the second nanostructure array NSA2′ includes second nanostructures NS2′ in which the inclination angle θ5 with respect to the first direction DR1 changes at a constant period along the first direction DR1 and the second direction DR2, and the third nanostructure array NSA3′ includes third nanostructures NS3′ in which the inclination angle θ6 with respect to the first direction DR1 changes at a constant period along the first direction DR1 and the second direction DR2, reflection of the external light (e.g., the external light EL of FIG. 8) incident on the display device may be blocked.

The low-refractive index layer LR may cover the first nanostructure array NSA1′, the second nanostructure array NSA2′, and the third nanostructure array NSA3′.

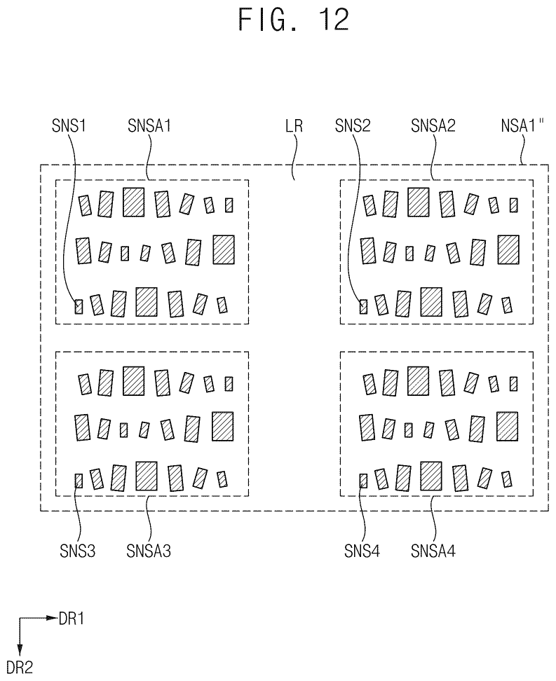

FIG. 12 is a plan view illustrating an example of a first nanostructure array included in the display device of FIG. 4.

Referring to FIG. 12, in an embodiment, the metasurface layer (e.g., the meta-surface layer MSL of FIG. 2) may include a first nanostructure array NSA1″. The first nanostructure array NSA1″ may be disposed in the first pixel area (e.g., the first pixel area PX1 of FIG. 3). In one or more embodiments, the first nanostructure array NSA1″ may include a first sub-nanostructure array SNSA1, a second sub-nanostructure array SNSA2, a third sub-nanostructure array SNSA3, and a fourth sub-nanostructure array SNSA4. The first sub-nanostructure array SNSA1, the second sub-nanostructure array SNSA2, the third sub-nanostructure array SNSA3, and the fourth sub-nanostructure array SNSA4 may be spaced apart from each other in a plan view. In an embodiment, for example, the second sub-nanostructure array SNSA2 may be spaced apart from the first sub-nanostructure array SNSA1 in the first direction DR1. The third sub-nanostructure array SNSA3 may be spaced apart from the first sub-nanostructure array SNSA1 in the second direction DR2. The fourth sub-nanostructure array SNSA4 may be spaced apart from the second sub-nanostructure array SNSA2 in the second direction DR2. The fourth sub-nanostructure array SNSA4 may be spaced apart from the third sub-nanostructure array SNSA3 in the first direction DR1.

FIG. 12 may illustrate an example in which the first nanostructure array NSA1″ includes four sub-nanostructures, but this disclosure is not limited thereto, and number of sub-nanostructures included in the first nanostructure array NSA1″ may be variously changed according to embodiments. In addition, the second nanostructure array (e.g., the second nanostructure array NSA2 of FIG. 4) disposed in the second pixel area (e.g., the second pixel area PX2 of FIG. 3) and the third nanostructure array (e.g., the third nanostructure array NSA3 of FIG. 4) disposed in the third pixel area (e.g., the third pixel area PX3 of FIG. 3) may also include a plurality of sub-nanostructures, like the first nanostructure array NSA1″.

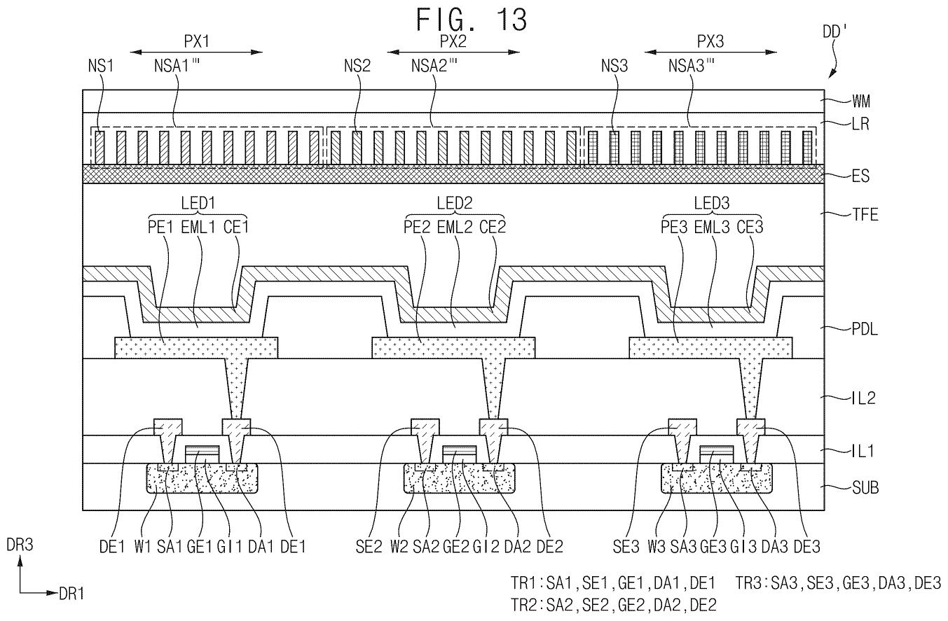

FIG. 13 is a cross-sectional view illustrating an example of the display device of FIG. 1 taken along line I-I′.

The display device DD′ of FIG. 13 is substantially the same as the display device DD of FIG. 3 except for a configuration of a first nanostructure array NSA1′″, a second nanostructure array NSA2′″, and a third nanostructure array NSA3′″. Therefore, any repetitive detailed descriptions of the same or like elements as those described above will be omitted or simplified.

Referring to FIG. 13, in an embodiment, the metasurface layer (e.g., the metasurface layer MSL of FIG. 2) may include a first nanostructure array NSA1′″, a second nanostructure array NSA2′″, and a third nanostructure array NSA3′″.

The first nanostructure array NSA1′″ may include first nanostructures NS1. The first nanostructures NS1 may be repeatedly arranged along the first direction DR1 and the second direction DR2. In an embodiment, for example, the first nanostructures NS1 may be repeatedly arranged along the first direction DR1 and the second direction DR2 in the first pixel area PX1. The first nanostructures NS1 may be spaced apart from each other in a plan view.

The second nanostructure array NSA′″ may include second nanostructures NS2. The second nanostructures NS2 may be repeatedly arranged along the first direction and the second direction DR2. In an embodiment, for example, the second nanostructures NS2 may be repeatedly arranged along the first direction DR1 and the second direction DR2 in the second pixel area PX2. The second nanostructures NS2 may be spaced apart from each other in a plan view.

The third nanostructure array NSA3′″ may include third nanostructures NS3. The third nanostructures NS3 may be repeatedly arranged along the first direction DR1 and the second direction DR2. In an embodiment, for example, the third nanostructures NS3 may be repeatedly arranged along the first direction DR1 and the second direction DR2 in the third pixel area PX3. The third nanostructures NS3 may be spaced apart from each other in a plan view.

In one or more embodiments, the first nanostructures NS1 may be disposed between the first pixel area PX1 and the second pixel area PX2. In an embodiment, for example, the first nanostructures NS1 may be disposed in the first pixel area PX1 and some areas adjacent to the first pixel area PX1. The second nanostructures NS2 may be disposed between the first pixel area PX1 and the second pixel area PX2. In addition, the second nanostructures NS2 may be disposed between the second pixel area PX2 and the third pixel area PX3. In an embodiment, for example, the second nanostructures NS2 may be disposed in the second pixel area PX2 and some areas adjacent to the second pixel area PX2. The third nanostructures NS3 may be disposed between the second pixel area PX2 and the third pixel area PX3. In an embodiment, for example, the third nanostructures NS3 may be disposed in the third pixel area PX3 and some areas adjacent to the third pixel area PX3.

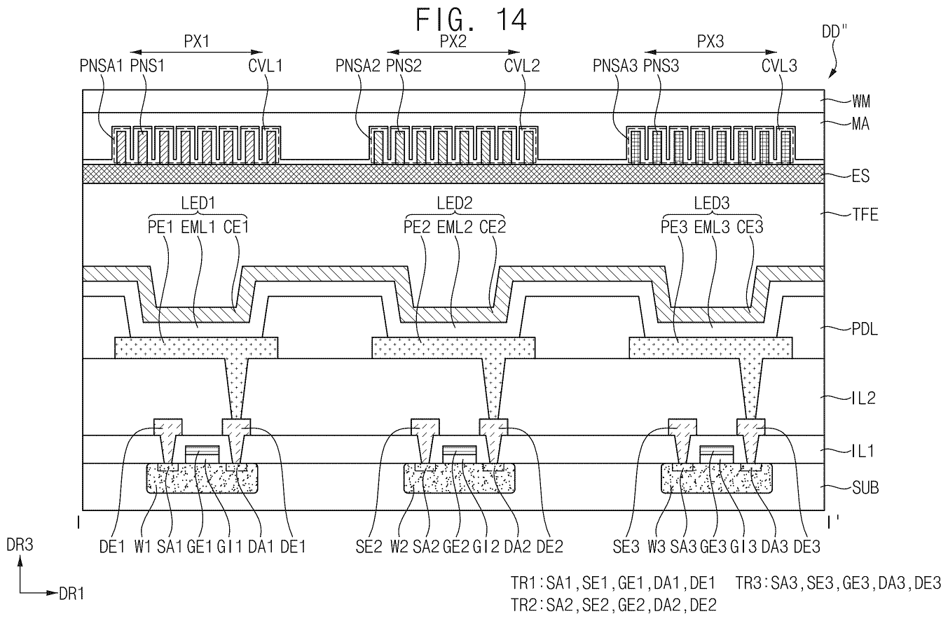

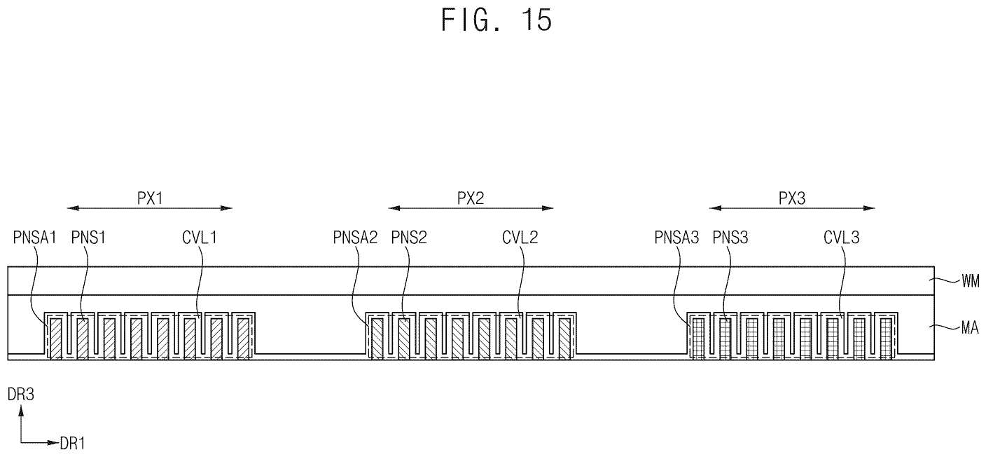

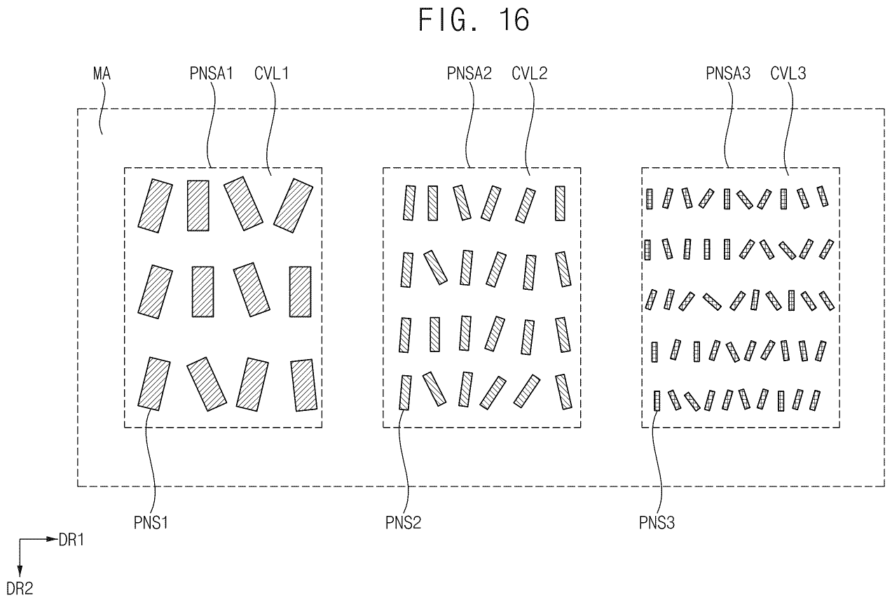

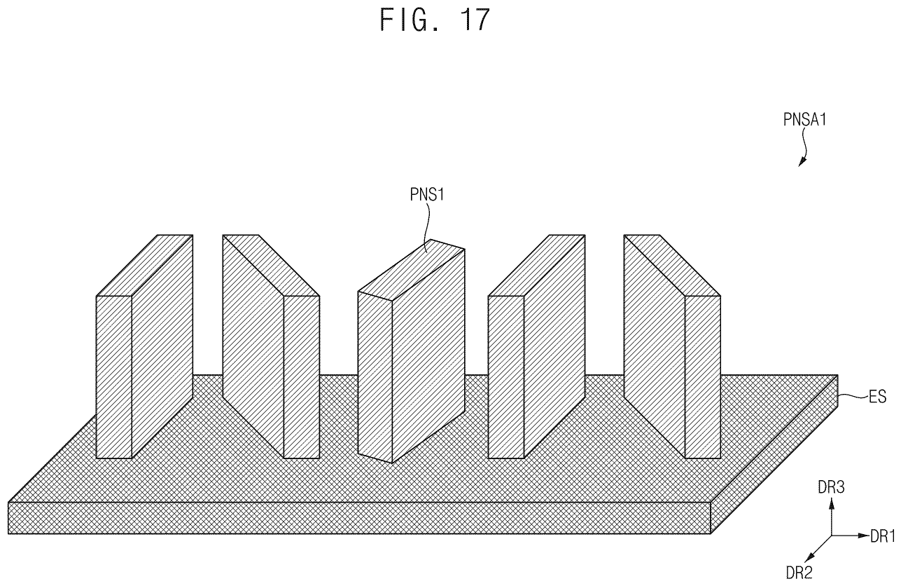

FIG. 14 is a cross-sectional view illustrating an example of the display device of FIG. 1 taken along line I-I′. FIG. 15 is a cross-sectional view illustrating a portion of the display device of FIG. 14. FIG. 16 is a plan view schematically illustrating a partial area of the display device of FIG. 14. FIG. 17 is a perspective view illustrating a first nanostructure array included in the display device of FIG. 16.

The display device DD″ of FIG. 14 is substantially the same as the display device DD of FIG. 3 except for a configuration of a first nanostructure array PNSA1, a second nanostructure array PNSA2, a third nanostructure array PNSA3, a first refractive layer CVL1, a second refractive layer CVL2, a third refractive layer CVL3, and a microlens layer MA. Therefore, any repetitive detailed descriptions of the same or like elements as those described above will be omitted or simplified.

Referring to FIGS. 14, 15, 16, and 17, an embodiment of a display device DD″ may include the metasurface layer (e.g., the metasurface layer MSL of FIG. 2), a first refractive layer CVL1, a second refractive layer CVL2, a third refractive layer CVL3, and a microlens layer MA. The metasurface layer may include a first nanostructure array PNSA1, a second nanostructure array PNSA2, and a third nanostructure array PNSA3.

The first nanostructure array PNSA1 may include first nanostructures PNS1. The first nanostructures PNS1 may be repeatedly arranged along the first direction DR1 and the second direction DR2. In an embodiment, for example, the first nanostructures PNS1 may be repeatedly arranged along the first direction DR1 and the second direction DR2 in the first pixel area PX1. The first nanostructures PNS1 may be spaced apart from each other in a plan view.

The second nanostructure array PNSA2 may include second nanostructures PNS2. The second nanostructures PNS2 may be repeatedly arranged along the first direction DR1 and the second direction DR2. In an embodiment, for example, the second nanostructures PNS2 may be repeatedly arranged in the first direction DR1 and the second DR2 in the second pixel area PX2. The second nanostructures PNS2 may be spaced apart from in a plan view.

The third nanostructure array PNSA3 may include third nanostructures PNS3. The third nanostructures PNS3 may be repeatedly arranged along the first direction DR1 and the second direction DR2. In an embodiment, for example, the third nanostructures PNS3 may be repeatedly arranged along the first direction DR1 and the second directions DR2 in the third pixel area PX3. The third nanostructures PNS3 may be spaced apart from each other in a plan view.

In one or more embodiments, like the first nanostructures NS1 described above with reference to FIG. 4, a degree of inclination of the first nanostructures PNS1 may be different depending on positions of the first nanostructures PNS1 in a plan view. In an embodiment, for example, degrees of inclination of adjacent first nanostructures of the first nanostructures PNS1 may be different from each other.

In one or more embodiments, like the second nanostructures NS2 described above with reference to FIG. 4, a degree of inclination of the second nanostructures PNS2 may be different depending on positions of the second nanostructures PNS2 in a plan view. In an embodiment, for example, degrees of inclination of adjacent second nanostructures of the second nanostructures PNS2 may be different from each other.

In one or more embodiments, like the third nanostructures NS3 described above with reference to FIG. 4, a degree of inclination of the third nanostructures PNS3 may be different depending on positions of the third nanostructures PNS3 in a plan view. In an embodiment, for example, degrees of inclination of adjacent third nanostructures of the third nanostructures PNS3 may be different from each other.

In one or more embodiments, unlike the first nanostructures NS1 of FIG. 4, a first length (e.g., the first length LA1 of FIG. 6) of the first nanostructures PNS1 may be constant regardless of positions of the first nanostructures PNS1 in a plan view. In an embodiment, for example, the first length of the first nanostructures PNS1 may be constant over the first pixel area PX1. In an embodiment, for example, lengths of the first nanostructures PNS1 in the horizontal direction may be constant over the first pixel area PX1. In one or more embodiments, unlike the first nanostructures NS1 of FIG. 4, a second length LA2 (e.g., the second length LA2 of FIG. 6) of the first nanostructures PNS1 may be constant regardless of positions of the first nanostructures PNS1 in a plan view. In an embodiment, for example, the second length of the first nanostructures PNS1 may be constant over the first pixel area PX1. In an embodiment, for example, the lengths of the first nanostructures PNS1 in the vertical direction may be constant over the first pixel area PX1. In one or more embodiments, unlike the first nanostructures NS1 of FIG. 4, a height (e.g., the height LA3 of FIG. 6) of the first nanostructures PNS1 may be constant regardless of positions of the first nanostructures PNS1 in a plan view. In an embodiment, for example, the height of the first nanostructures PNS1 may be constant over the first pixel area PX1. In an embodiment, for example, a volume of the first nanostructures PNS1 may be constant over the first pixel area PX1.

In one or more embodiments, unlike the second nanostructures NS2 of FIG. 4, a first length (e.g., the first length LB1 of FIG. 6) of the second nanostructures PNS2 may be constant regardless of positions of the second nanostructures PNS2 in a plan view. In an embodiment, for example, the first length of the second nanostructures PNS2 may be constant over the first pixel area PX1. In an embodiment, for example, lengths of the second nanostructures PNS2 in the horizontal direction may be constant over the first pixel area PX1. In one or more embodiments, unlike the second nanostructures NS2 of FIG. 4, a second length LB2 (e.g., the second length LB2 of FIG. 6) of the second nanostructures PNS2 may be constant regardless of positions of the second nanostructures PNS2 in a plan view. In an embodiment, for example, the second length of the second nanostructures PNS2 may be constant over the first pixel area PX1. In an embodiment, for example, the lengths of the second nanostructures PNS2 in the vertical direction may be constant over the first pixel area PX1. In one or more embodiments, unlike the second nanostructures NS2 of FIG. 4, a height (e.g., the height LB3 of FIG. 6) of the second nanostructures PNS2 may be constant regardless of positions of the second nanostructures PNS2 in a plan view. In an embodiment, for example, the height of the second nanostructures PNS2 may be constant over the first pixel area PX1. In an embodiment, for example, a volume of the second nanostructures PNS2 may be constant over the first pixel area PX1.

In one or more embodiments, unlike the third nanostructures NS3 of FIG. 4, a first length (e.g., the first length LC1 of FIG. 6) of the third nanostructures PNS3 may be constant regardless of positions of the third nanostructures PNS3 in a plan view. In an embodiment, for example, the first length of the third nanostructures PNS3 may be constant over the first pixel area PX1. In an embodiment, for example, lengths of the third nanostructures PNS3 in the horizontal direction may be constant over the first pixel area PX1. In one or more embodiments, unlike the third nanostructures NS3 of FIG. 4, a second length LC2 (e.g., the second length LC2 of FIG. 6) of the third nanostructures PNS3 may be constant regardless of positions of the third nanostructures PNS3 in a plan view. In an embodiment, for example, the second length of the third nanostructures PNS3 may be constant over the first pixel area PX1. In an embodiment, for example, the lengths of the third nanostructures PNS3 in the vertical direction may be constant over the first pixel area PX1. In one or more embodiments, unlike the third nanostructures NS3 of FIG. 4, a height (e.g., the height LC3 of FIG. 6) of the third nanostructures PNS3 may be constant regardless of positions of the third nanostructures PNS3 in a plan view. In an embodiment, for example, the height of the third nanostructures PNS3 may be constant over the first pixel area PX1. In an embodiment, for example, a volume of the third nanostructures PNS3 may be constant over the first pixel area PX1.

In one or more embodiments, as described above, the degree of inclination of the first nanostructures PNS1 may change depending on the positions of the first nanostructures PNS1 in a plan view. The degree of inclination of the second nanostructures PNS2 may change depending on the positions of the second nanostructures PNS2 in a plan view. The degree of inclination of the third nanostructures PNS3 may change depending on the positions of the third nanostructures PNS3 in a plan view. Accordingly, as described above with reference to FIG. 8, reflection of external light (e.g., external light EL of FIG. 8) incident on the display device DD″ may be blocked even when a separate polarizing plate and/or the like is not disposed on the first light-emitting element LED1, the second light-emitting element LED2, and the third light-emitting element LED3.

In such an embodiment, as the first length, the second length, and the height of the first nanostructures PNS1 are constant over the first pixel area PX1, the first nanostructures PNS1 may not increase efficiency and intensity of the first light (e.g., the first light L1 of FIG. 7). In such an embodiment, the first refractive layer CVL1 and the microlens layer MA may increase the efficiency and intensity of the first light. In such an embodiment, as the first length, the second length, and the height of the second nanostructures PNS2 are constant over the second pixel area PX2, the second nanostructures PNS2 may not increase efficiency and intensity of the second light (for example, the second light L2 of FIG. 7). In such an embodiment, the second refractive layer CVL2 and the microlens layer MA may increase the efficiency and intensity of the second light. In such an embodiment, as the first length, the second length, and the height of the third nanostructures PNS3 are constant over the third pixel area PX3, the third nanostructures PNS3 may not increase efficiency and intensity of the third light (for example, the third light L3 of FIG. 7). In such an embodiment, the third refractive layer CVL3 and the microlens layer MA may increase the efficiency and intensity of the second light. The first refractive layer CVL1, the second refractive layer CVL2, the third refractive layer CVL3, and the microlens layer MA will be described below.

The first refractive layer CVL1 may be disposed on the etch stopper ES. The first refractive layer CVL1 may be disposed in the first pixel area PX1. The first refractive layer CVL1 may cover the first nanostructures PNS1 in the first pixel area PX1. In an embodiment, for example, the first refractive layer CVL1 may cover a side surface and an upper surface of each of the first nanostructures PNS1. The first refractive layer CVL1 may include a material having a high refractive index. In an embodiment, for example, a refractive index of the first refractive layer CVL1 may be equal to or greater than about 4 and equal to or less than about 4.5. In an embodiment, for example, the refractive index of the first refractive layer CVL1 may be about 4.2. Examples of material that may be used as the first refractive layer CVL1 may include amorphous silicon, but this disclosure is not limited thereto.

The second refractive layer CVL2 may be disposed on the etch stopper ES. The second refractive layer CVL2 may be disposed in the second pixel area PX2. The second refractive layer CVL2 may cover the second nanostructures PNS2 in the second pixel area PX2. In an embodiment, for example, the second refractive layer CVL2 may cover a side surface and an upper surface of each of the second nanostructures PNS2. The second refractive layer CVL2 may include a material having a high refractive index. In an embodiment, for example, a refractive index of the second refractive layer CVL2 may be equal to or greater than about 4 and equal to or less than about 4.5. In an embodiment, for example, the refractive index of the second refractive layer CVL2 may be about 4.2. Examples of material that may be used as the second refractive layer CVL2 may include amorphous silicon, but this disclosure is not limited thereto. In one or more embodiments, the second refractive layer CVL2 may be connected to the first refractive layer CVL1. In an embodiment, for example, the first refractive layer CVL1 and the second refractive layer CVL2 may be integrally formed with each other as a single unitary indivisible part, but this disclosure is not limited thereto, and the second refractive layer CVL2 may be separated from the first refractive layer CVL1.

The third refractive layer CVL3 may be disposed on the etch stopper ES. The third refractive layer CVL3 may be disposed in the third pixel area PX3. The third refractive layer CVL3 may cover the third nanostructures PNS3 in the third pixel area PX3. In an embodiment, for example, the third refractive layer CVL3 may cover a side surface and an upper surface of each of the third nanostructures PNS3. The third refractive layer CVL3 may include a material having a high refractive index. In an embodiment, for example, a refractive index of the third refractive layer CVL3 may be equal to or greater than about 4 and equal to or less than about 4.5. In an embodiment, for example, the refractive index of the third refractive layer CVL3 may be about 4.2. Examples of material that may be used as the third refractive layer CVL3 may include amorphous silicon, but this disclosure is not limited thereto. In one or more embodiments, the third refractive layer CVL3 may be connected to the second refractive layer CVL2. In an embodiment, for example, the second refractive layer CVL2 and the third refractive layer CVL3 may be integrally formed with each other as a single unitary indivisible part, but this disclosure is not limited thereto, and the third refractive layer CVL3 may be separated from the second refractive layer CVL2.

The microlens layer MA may be disposed on the first refractive layer CVL1, the second refractive layer CVL2, and the third refractive layer CVL3. In an embodiment, for example, the microlens layer MA may cover the first refractive layer CVL1, the second refractive layer CVL2, and the third refractive layer CVL3. The microlens layer MA may function as a planarization layer for providing a planarized upper surface on the first nanostructures PNS1, the second nanostructures PNS2, and the third nanostructures PNS3. In one or more embodiments, the microlens layer MA may be continuously disposed over the first pixel area PX1, the second pixel area PX2, and the third pixel area PX3. A refractive index of the microlens layer MA may be equal to or greater than about 1.6 and equal to or less than about 1.7. In an embodiment, for example, the refractive index of the microlens layer MA may be about 1.63. The microlens layer MA may include an organic material. In an embodiment, for example, the microlens layer MA may include a polymer organic material, but this disclosure is not limited thereto.

The microlens layer MA disposed in the first pixel area PX1 and the first refractive layer CVL1 may increase the efficiency and intensity of first light (e.g., the first light L1 of FIG. 7). However, this disclosure is not necessarily limited thereto, and the first refractive layer CVL1 may be omitted. In an embodiment, the microlens layer MA disposed in the first pixel area PX1 may increase the efficiency and intensity of the first light. The microlens layer MA disposed in the second pixel area PX2 and the second refractive layer CVL2 may increase the efficiency and intensity of second light (e.g., the second light L2 of FIG. 7). However, this disclosure is not necessarily limited thereto, and the second refractive layer CVL2 may be omitted. In an embodiment, the microlens layer MA disposed in the second pixel area PX2 may increase the efficiency and intensity of the second light. The microlens layer MA disposed in the third pixel area PX3 and the third refractive layer CVL3 may increase the efficiency and intensity of third light (e.g., the third light L3 of FIG. 7). However, this disclosure is not necessarily limited thereto, and the third refractive layer CVL3 may be omitted. In an embodiment, the microlens layer MA disposed in the third pixel area PX3 may increase the efficiency and intensity of the third light.

The display device (e.g., the display device DD of FIG. 1) according to embodiments may be applied to various electronic devices. An electronic device according to embodiments may include the above-described display device, and may further include a module or device having other additional functions in addition to the display device.

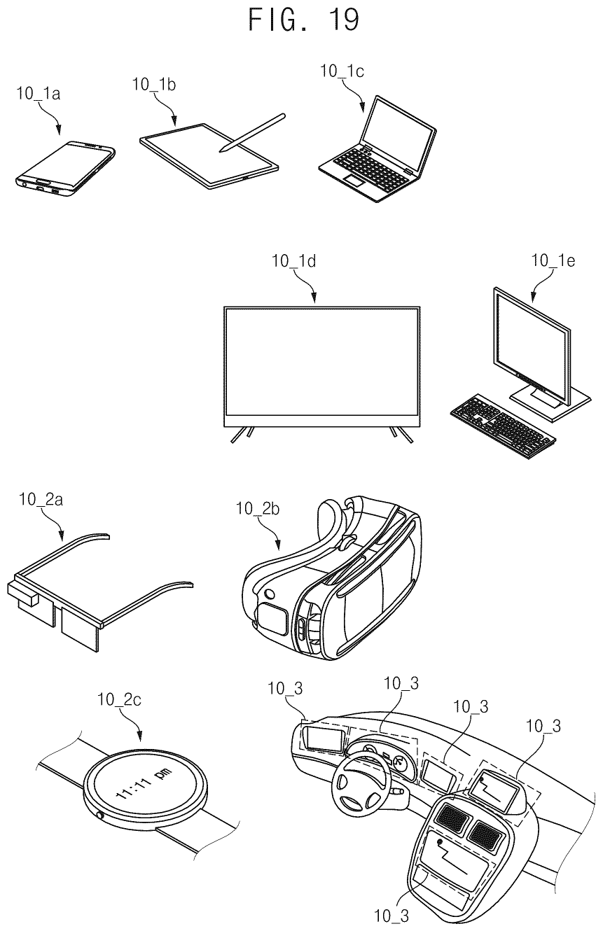

FIG. 19 is a block diagram illustrating an electronic device according to embodiments.

Referring to FIG. 19, an electronic device 10 according to embodiments may include a display module 11, a processor 12, a memory 13, and a power module 14.

The processor 12 may include at least one selected from a central processing unit (“CPU”), an application processor (“AP”), a graphic processing unit (“GPU”), a communication processor (“CP”), an image signal processor (“ISP”), and a controller.

Data information necessary for operation of the processor 12 or the display module 11 may be stored in the memory 15. When the processor 12 executes an application stored in the memory 15, an image data signal and/or an input control signal is transmitted to the display module 11, and the display module 11 may process received signal and output image information through a display screen.

The power module 14 may include a power supply module such as a power adapter or a battery device, and a power conversion module that converts power supplied by the power supply module to generate power required for operation of the electronic device 10.

At least one of components of the electronic device 10 described above may be included in the display device according to the above-described embodiments. In addition, some of individual modules functionally included in one module may be included in the display device, and others may be provided separately from the display device. In an embodiment, for example, the display device may include the display module 11, and the processor 12, the memory 13, and the power module 14 may be provided in form of another device in the electronic device 10 other than the display device.

FIG. 20 is a schematic diagram of an electronic device according to various embodiments.

Referring to FIG. 20, various electronic devices to which display devices according to embodiments are applied may include not only electronic devices for image display such as a smartphone 10_1a, a tablet PC 10_1b, a laptop 10_1c, a TV 10_1d, a desk monitor 10_1e, and/or the like, but also wearable electronic devices including display modules such as a smart glass 10_2a, a head mounted display 10_2b, a smart watch 10_2c, and/or the like, vehicle electronic device 10_3 including display modules such as a vehicle's instrument panel, a center fascia, a center information display (“CID”) disposed on a dashboard, a room mirror display, and/or the like.

Embodiments of the present disclosure can be applied to various display devices such as display devices for vehicles, ships and aircraft, portable communication devices, display devices for exhibition or information transmission, medical display devices, and the like, for example.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a first light-emitting element located in a first pixel area;
a first nanostructure array located in the first pixel area on the first light-emitting element, wherein the first nanostructure array includes first nanostructures repeatedly arranged along a first direction and a second direction crossing the first direction, wherein lengths of the first nanostructures in a horizontal direction thereof change along the first direction;
a second light-emitting element located in a second pixel area spaced apart from the first pixel area in a plan view; and
a second nanostructure array located in the second pixel area on the second light-emitting element, wherein the second nanostructure array includes second nanostructures repeatedly arranged along the first direction and the second direction, wherein lengths of the second nanostructures in a horizontal direction thereof change along the first direction.

2. The display device of claim 1, wherein lengths of the first nanostructures in a vertical direction thereof change along the first direction and lengths of the second nanostructures in a vertical direction thereof change along the first direction.

3. The display device of claim 1, wherein the lengths of the first nanostructures in the horizontal direction thereof change along the second direction, and the lengths of the second nanostructures in the horizontal direction thereof change along the second direction.

4. The display device of claim 1, wherein a separation distance between two adjacent first nanostructures of the first nanostructures and a separation distance between two adjacent second nanostructures of the second nanostructures are different from each other.

5. The display device of claim 4, wherein
the first pixel area emits red light,
the second pixel area emits green light, and
the separation distance between the two adjacent first nanostructures of the first nanostructures is greater than the separation distance between the two adjacent second nanostructures of the second nanostructures.

6. The display device of claim 1, wherein heights of the first nanostructures change along the first direction and heights of the second nanostructures change along the first direction.

7. The display device of claim 6, wherein the heights of the first nanostructures change along the second direction and the heights of the second nanostructures change along the second direction.

8. The display device of claim 1, wherein inclination angles of the first nanostructures with respect to the first direction change along the first direction and inclination angles of the second nanostructures with respect to the first direction change along the first direction.

9. The display device of claim 8, wherein the inclination angles of the first nanostructures with respect to the first direction change along the second direction and the inclination angles of the second nanostructures with respect to the first direction change along the second direction.

10. The display device of claim 1, wherein the lengths of the first nanostructures in the horizontal direction thereof change gradually along the first direction and the lengths of the second nanostructures in the horizontal direction thereof change gradually along the first direction.

11. The display device of claim 1, wherein at least one of the first nanostructures are located between the first pixel area and the second pixel area.

12. The display device of claim 11, wherein at least one of the second nanostructures are located between the first pixel area and the second pixel area.

13. The display device of claim 1, wherein the first nanostructure array includes sub-nanostructure arrays spaced apart from each other in a plan view.

14. A display device comprising:
a first light-emitting element located in a first pixel area;
a first nanostructure array located in the first pixel area on the first light-emitting element, wherein the first nanostructure array includes first nanostructures repeatedly arranged along a first direction and a second direction crossing the first direction, wherein inclination angles of the first nanostructures with respect to the first direction change along the first direction;
a second light-emitting element located in a second pixel area spaced apart from the first pixel area in a plan view; and
a second nanostructure array located in the second pixel area on the second light-emitting element, wherein the second nanostructure array includes second nanostructures repeatedly arranged along the first direction and the second direction, wherein inclination angles of the second nanostructures with respect to the first direction change along the first direction.

15. The display device of claim 14, wherein the inclination angles of the first nanostructures with respect to the first direction change along the second direction and the inclination angles of the second nanostructures with respect to the first direction change along the second direction.

16. The display device of claim 14, wherein a separation distance between two adjacent first nanostructures of the first nanostructures and a separation distance between two adjacent second nanostructures of the second nanostructures are different from each other.

17. The display device of claim 16, wherein
the first pixel area emits red light,
the second pixel area emits green light, and
the separation distance between the two adjacent first nanostructures of the first nanostructures is greater than the separation distance between the two adjacent second nanostructures of the second nanostructures.

18. The display device of claim 14, wherein each of the first nanostructures has an elliptical pillar shape,
lengths of a major axis of the first nanostructures change along the first direction,
each of the second nanostructures has an elliptical pillar shape, and
lengths of a major axis of the second nanostructures change along the first direction.

19. The display device of claim 14, further comprising:
a first refractive layer covering the first nanostructures;
a second refractive layer covering the second nanostructures; and
a microlens layer covering the first refractive layer and the second refractive layer.

20. An electronic device comprising:
a first light-emitting element located in a first pixel area;
a first nanostructure array located in the first pixel area on the first light-emitting element, wherein the first nanostructure array includes first nanostructures repeatedly arranged along a first direction and a second direction crossing the first direction, wherein lengths of the first nanostructures in a horizontal direction thereof change along the first direction;
a second light-emitting element located in a second pixel area spaced apart from the first pixel area in a plan view;
a second nanostructure array located in the second pixel area on the second light-emitting element, wherein the second nanostructure array includes second nanostructures repeatedly arranged along the first direction and the second direction, wherein lengths of the second nanostructures in a horizontal direction thereof change along the first direction; and
a memory configured to store data information.
